(19) United States
(12) Patent Application Publication
(10) Pub. No.: US 2026/0047317 A1
(43) Pub. Date: Feb. 12, 2026

(54) ORGANIC LIGHT EMITTING ELEMENT

(71) Applicant: TAIZHOU GUANYU TECHNOLOGY CO., LTD., ZHEJIANG PROVINCE (CN)

(72) Inventors: HUEI-SIOU CHEN, TAIPEI CITY (TW); LI-CHEN WEI, TAICHUNG CITY (TW)

(21) Appl. No.: 19/258,925

(22) Filed: Jul. 3, 2025

(30) Foreign Application Priority Data
Aug. 9, 2024 (CN) 202411092372.1

(51) Int. Cl. H10K 59/80; H10K 59/12

(52) U.S. Cl. CPC H10K 59/80523; H10K 59/1201

(57) ABSTRACT

An organic light emitting element includes a substrate, a first electrode, a first organic light emitting layer and a top electrode. The first electrode is located over the substrate. The first organic light emitting layer is located over the first electrode. The top electrode includes an electrode layer and a conductivity enhancer. The electrode layer is located over the first organic light emitting layer. The conductivity enhancer at least partially covers the electrode layer.

### BACKGROUND OF THE PRESENT DISCLOSURE

### Field of the Present Disclosure

The present disclosure relates to an organic light emitting element, and more particularly to an organic light emitting element including an organic light emitting diode (OLED) structure.

### Description of the Prior Art

Currently, a fine metal mask (FMM) is commonly used in a coating step for a light emitting layer of an organic light emitting element, or white light in combination with a color film are used for a manufacturing process. However, fineness or resolution of pixels resulted from the manufacturing process above is rather poor.

### Summary of the Present Disclosure

In the present disclosure, an organic light emitting element includes a substrate, a first electrode, a first organic light emitting layer and a top electrode. The first electrode is over the substrate. The first organic light emitting layer is over the first electrode. The top electrode includes an electrode layer and a conductivity enhancer. The electrode layer is over the first organic light emitting layer. The conductivity enhancer at least partially covers the electrode layer.

In the present disclosure, a manufacturing method of an organic light emitting element includes: providing a substrate; disposing a first electrode over the substrate; forming a first organic light emitting layer over the first electrode; forming an electrode layer over the first organic light emitting layer; and forming a conductivity enhancer over the electrode layer to partially cover the electrode layer.

In some embodiments, the conductivity enhancer substantially completely covers the electrode layer.

In some embodiments, the organic light emitting element further includes a second electrode and a second organic light emitting layer. The second electrode is over the substrate. The second organic light emitting layer is over the second electrode, a thickness of the second organic light emitting layer is greater than a thickness of the first organic light emitting layer, and the conductivity enhancer contacts and covers the electrode layer above the second organic light emitting layer.

In some embodiments, the electrode layer includes a first metal material, the conductivity enhancer includes a second metal material different from the first metal material, and a compressive strength of the second metal material is greater than a compressive strength of the first metal material.

In some embodiments, the electrode layer includes a silver layer, and the conductivity enhancer includes a transparent conductive material.

In some embodiments, the transparent conductive material includes a conductive metal oxide.

In some embodiments, the organic light emitting element further includes a first insulating protrusion and a second insulating protrusion on the substrate, the first organic light emitting layer is in a recess between the first insulating protrusion and the second insulating protrusion, and the conductivity enhancer is at least partially above the first insulating protrusion and the second insulating protrusion.

In some embodiments, the conductivity enhancer is at least partially not located above the first organic light emitting layer.

In some embodiments, from a cross-sectional view perspective, the conductivity enhancer includes a first portion covering the first insulating protrusion and a second portion covering the second insulating protrusion, and the first portion and the second portion have different thicknesses.

In some embodiments, the electrode layer is at least partially not located at a top portion of the first insulating protrusion and a top portion of the second insulating portion.

In some embodiments, the electrode layer and the conductive enhancer include the same metal material.

In some embodiments, the organic light emitting element further includes a second electrode and a second organic light emitting layer. The second electrode is over the substrate. The second organic light emitting layer is over the second electrode, a thickness of the second organic light emitting layer is greater than a thickness of the first organic light emitting layer, and the conductivity enhancer is at least partially above the second organic light emitting layer.

In some embodiments, the conductivity enhancer is at least partially not located above the first organic light emitting layer.

In some embodiments, a luminescence wavelength of the second organic light emitting layer is greater than a luminescence wavelength of the first organic light emitting layer.

In some embodiments, the first organic light emitting layer is formed at a first process temperature, the conductivity enhancer is formed at a second process temperature, and the second process temperature is less than the first process temperature.

In some embodiments, the electrode layer includes silver, and the conductivity enhancer includes indium zinc oxide (IZO).

In some embodiments, the manufacturing method of an organic light emitting element further includes: disposing a second electrode over the substrate; and forming a second organic light emitting layer over the second electrode, wherein a thickness of the second organic light emitting layer is greater than a thickness of the first organic light emitting layer, and the conductivity enhancer is at least partially above the second organic light emitting layer.

In some embodiments, the manufacturing method of an organic light emitting element further includes: forming a first insulating protrusion and a second insulating protrusion on the substrate, wherein the first organic light emitting layer is formed in a recess between the first insulating protrusion and the second insulating protrusion, and the conductivity enhancer is at least partially formed above the first insulating protrusion and the second insulating protrusion.

In some embodiments, the electrode layer is at least partially not formed at a top portion of the first insulating protrusion and a top portion of the second insulating portion.

In some embodiments, the conductivity enhancer is at least partially not formed above the first organic light emitting layer.

### BRIEF DESCRIPTION OF THE DRAWINGS

FIG. 1 is a top view of an exemplary intermediate product of an organic light emitting element.

FIG. 2 is a cross-sectional diagram taken along the line A-A′ in FIG. 1 according to some embodiments.

FIG. 2A is a cross-sectional diagram of the organic light emitting unit in FIG. 2.

FIG. 2B is a cross-sectional diagram of the organic light emitting unit in FIG. 2.

FIG. 2C is a cross-sectional diagram of the organic light emitting unit in FIG. 2.

FIG. 3A is a cross-sectional diagram taken along the line A-A′ in FIG. 1 according to some embodiments.

FIG. 3B is a cross-sectional diagram taken along the line A-A′ in FIG. 1 according to some embodiments.

FIG. 3C is a cross-sectional diagram taken along the line A-A′ in FIG. 1 according to some embodiments.

FIG. 3D is a cross-sectional diagram taken along the line A-A′ in FIG. 1 according to some embodiments.

FIG. 3E is a cross-sectional diagram taken along the line A-A′ in FIG. 1 according to some embodiments.

FIG. 3F is a cross-sectional diagram taken along the line A-A′ in FIG. 1 according to some embodiments.

FIG. 4A is a cross-sectional diagram taken along the line A-A′ in FIG. 1 according to some embodiments.

FIG. 4B is a cross-sectional diagram taken along the line A-A′ in FIG. 1 according to some embodiments.

FIG. 4C is a cross-sectional diagram taken along the line A-A′ in FIG. 1 according to some embodiments.

FIG. 4D is a cross-sectional diagram taken along the line A-A′ in FIG. 1 according to some embodiments.

FIG. 4E is a cross-sectional diagram taken along the line A-A′ in FIG. 1 according to some embodiments.

FIG. 5A to FIG. 5I depict a manufacturing method of an organic light emitting element according to some embodiments.

FIG. 6A to FIG. 6D depict a manufacturing method of an organic light emitting element according to some embodiments.

### DETAILED DESCRIPTION OF THE EMBODIMENTS

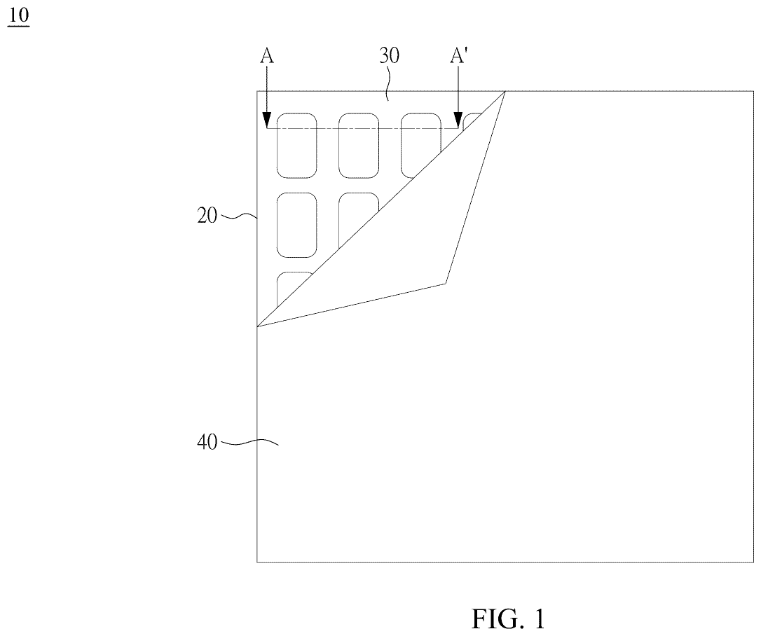

FIG. 1 shows a top view of an exemplary intermediate product of an organic light emitting element 10. The light emitting element 10 includes a light emitting layer 20 and a cover layer 40 over the light emitting layer 20. For the light emitting layer 20, a spacer structure 30 may be designed to provide a recess array used to accommodate a light emitting pixel array. In some embodiments, the spacer structure 30 may include a protrusion 310. In some embodiments, the spacer structure 30 may include a photosensitive material.

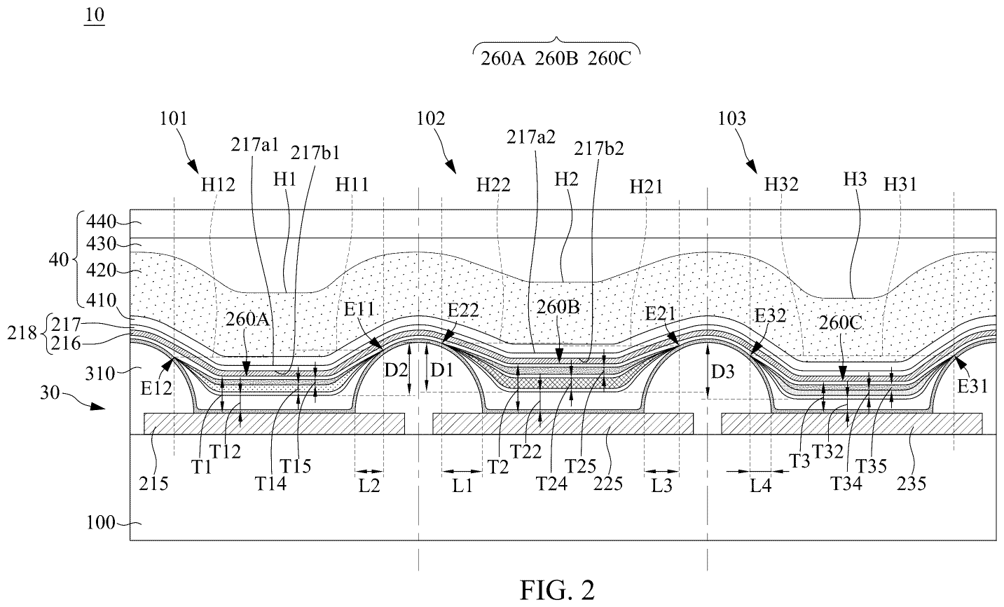

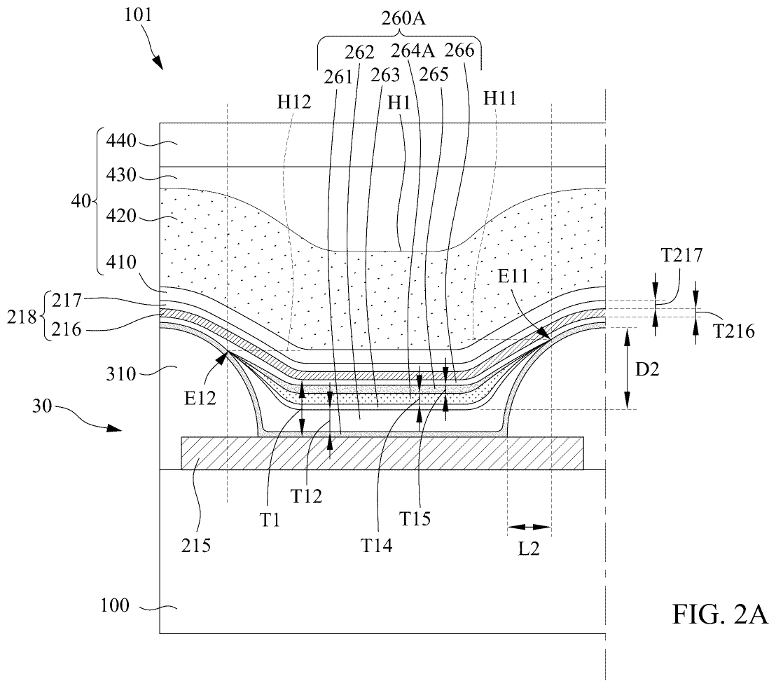

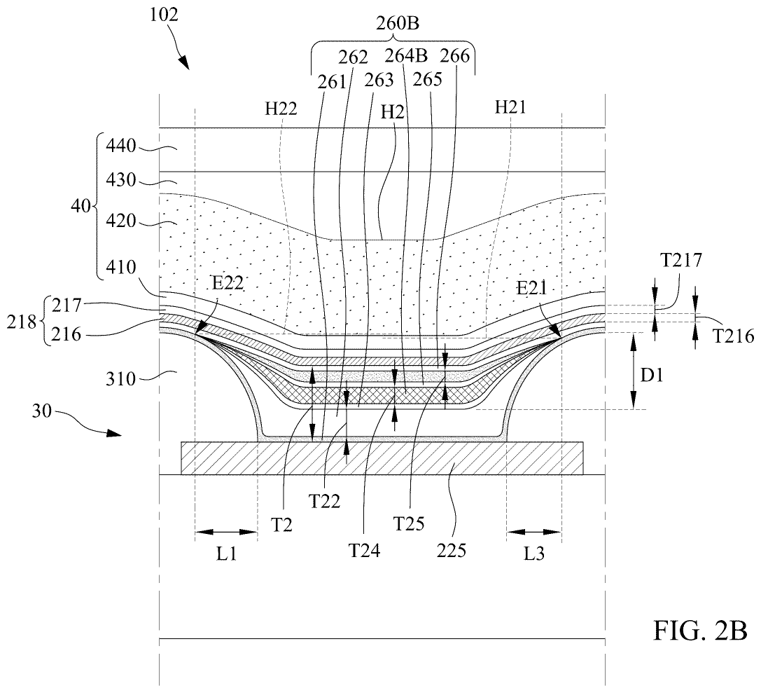

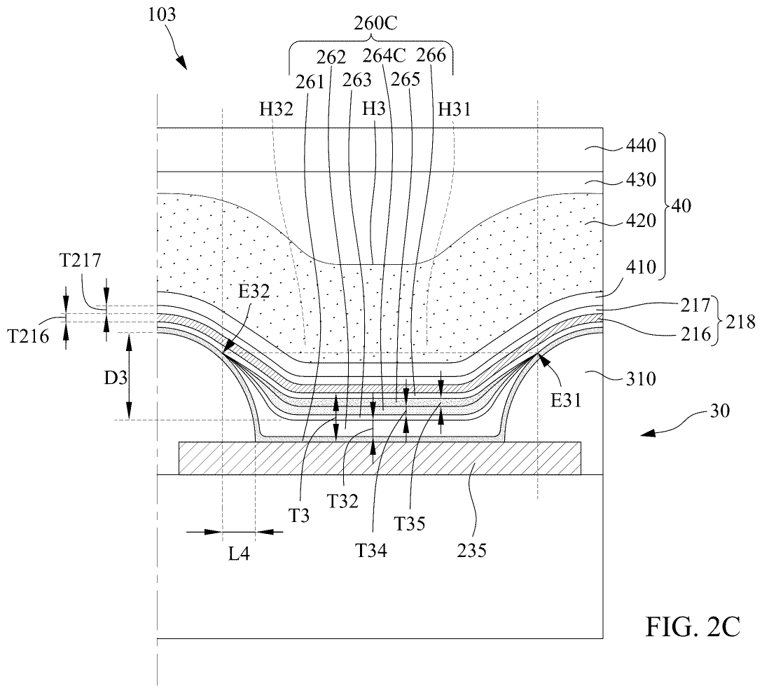

FIG. 2 shows a cross-sectional diagram taken along the line A-A′ in FIG. 1 according to some embodiments. FIG. 2A shows a cross-sectional diagram of the organic light emitting unit 101 in FIG. 2. FIG. 2B shows a cross-sectional diagram of the organic light emitting unit 102 in FIG. 2. FIG. 2C shows a cross-sectional diagram of the organic light emitting unit 103 in FIG. 2. In some embodiments, FIG. 2 shows a cross-sectional diagram taken along the line A-A′ in FIG. 1 as an example, and only a light emitting region is illustrated. The spacer structure 30 includes a plurality of protrusions 310 (or referred to as insulating protrusions) to define a light emitting pixel pattern. A recess is between two adjacent ones of the protrusions 310 and provides a space for accommodating light emitting pixels. When viewing the cross-sectional diagrams shown in FIG. 2, FIG. 2A FIG. 2B and FIG. 2C, a person skilled in the art would be able to understand that the protrusions 310 are depicted in a disconnected manner. However, when viewing the schematic top view of FIG. 1, the protrusions 310 can be connected to one another by other parts of the spacer structure 30.

As shown in FIG. 2, in some embodiments, the organic light emitting element 10 is, for example, a light emitting element including an organic light emitting diode (OLED) structure. In some embodiments, the light emitting element 10 includes a plurality of organic light emitting units (or referred to as light emitting pixels), for example, including at least an organic light emitting unit 101 (or referred to as a first organic light emitting unit), an organic light emitting unit 102 (or referred to as a second organic light emitting unit), and an organic light emitting unit 103 (or referred to as a third organic light emitting unit). In some embodiments, the organic light emitting units 101, 102 and 103 are between the protrusions 310 and above the substrate 100. The organic light emitting units 101, 102 and 103 may emit light having the same wavelength or light having different wavelengths.

In some embodiments, the organic light emitting element 10 includes a substrate 100, an electrode 215 (or referred to as a first electrode), an electrode 225 (or referred to as a second electrode), an electrode 235 (or referred to as a third electrode), an electrode 218 (or referred to as a top electrode or a common electrode), the light emitting layer 20, the spacer structure 30, and the cover layer 40.

In some embodiments, the substrate 100 may include a transistor array, which is configured to correspond to light emitting pixels in the light emitting layer 20. The substrate 100 may include a plurality of capacitors. In some embodiments, more than one transistor is configured with one capacitor and one light emitting pixel to form a circuit. In some embodiments, the substrate 100 may include glass.

In some embodiments, the electrodes 215, the electrode 225 and the electrode 235 are on the substrate 100. In some embodiments, the electrodes 215, 225 and 235 are anodes. In some embodiments, the electrodes 215, 225 and 235 include a metal material, for example, Ag, Al, Mg, Au, AlCu alloy or AgMo alloy. In some embodiments, the electrodes 215, 225 and 235 include indium tin oxide (ITO), indium zinc oxide (IZO) or other appropriate materials.

In some embodiments, the light emitting layer 20 includes an organic light emitting layer 260A (or referred to as a first organic light emitting layer), an organic light emitting layer 260B (or referred to as a second organic light emitting layer) and an organic light emitting layer 260C (or referred to as a third organic light emitting layer). In some embodiments, the organic light emitting layer 260A is over the electrode 215, the organic light emitting layer 260B is over the electrode 225, and the organic light emitting layer 260C is over the electrode 235. In some embodiments, each of the organic light emitting layers 260A, 260B and 260C is in a recess between two adjacent ones of the protrusions 310 (or referred to as the insulating protrusions).

In some embodiments, the organic material layers of the organic light emitting layers 260A, 260B and 260C include an organic material, which may be placed in any one of the organic material layers of the organic light emitting layers 260A, 260B and 260C according to different embodiments. In some embodiments, the organic material has an absorption rate of greater than or equal to 50% for a specific wavelength. In some embodiments, the organic material has an absorption rate of greater than or equal to 60% for a specific wavelength. In some embodiments, the organic material has an absorption rate of greater than or equal to 70% for a specific wavelength. In some embodiments, the organic material has an absorption rate of greater than or equal to 80% for a specific wavelength. In some embodiments, the organic material has an absorption rate of greater than or equal to 90% for a specific wavelength. In some embodiments, the organic material has an absorption rate of greater than or equal to 95% for a specific wavelength. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

In some embodiments, the organic light emitting layers 260A, 260B and 260C emit light in the same color or different colors. In some embodiments, a luminescence wavelength of the organic light emitting layer 260B is greater than a luminescence wavelength of the organic light emitting layer 260A, and the luminescence wavelength of the organic light emitting layer 260A is greater than a luminescence wavelength of the organic light emitting layer 260C. In some embodiments, the organic light emitting layer 260A emits green light, the organic light emitting layer 260B emits red light, and the organic light emitting layer 260C emits blue light.

In some embodiments, a thickness T1 of the organic light emitting layer 260A, a thickness T2 of the organic light emitting layer 260B and a thickness T3 of the organic light emitting layer 260C are different from one another. In some embodiments, the thickness T2 of the organic light emitting layer 260B is greater than the thickness T1 of the organic light emitting layer 260A, and the thickness T1 of the organic light emitting layer 260A is greater than the thickness T3 of the organic light emitting layer 260C. In some embodiments, an elevation of an upper surface of the organic light emitting layer 260B is higher than an elevation of an upper surface of the organic light emitting layer 260A. In some embodiments, the elevation of the upper surface of the organic light emitting layer 260A is higher than an elevation of an upper surface of the organic light emitting layer 260C.

In some embodiments, according to simulation results of influences of factors on the performance of microcavities, optimal luminescence performance is achieved when each of different organic light emitting layers is designed to have a total thickness that is one-half of a wavelength of the emitted light thereof. Thus, in some embodiments, the luminescence wavelength of the organic light emitting layer 260B is greater than the luminescence wavelength of the organic light emitting layer 260A, and the luminescence wavelength of the organic light emitting layer 260A is greater than the luminescence wavelength of the organic light emitting layer 260C. Hence, the thickness T2 of the organic light emitting layer 260B is greater than the thickness T1 of the organic light emitting layer 260A, and the thickness T1 of the organic light emitting layer 260A is greater than the thickness T3 of the organic light emitting layer 260C. As such, the organic light emitting element 10 can provide better luminescence performance.

As shown in FIG. 2A, in some embodiments, the organic light emitting unit 101 includes the electrode 215 (or referred to as the first electrode), the organic light emitting layer 260A, and the electrode 218 (or referred to as the top electrode or the common electrode). In some embodiments, the organic light emitting layer 260A includes a plurality of organic material layers, for example, a hole injection layer (HIL) 261, a hole transport layer (HTL) 262 (or referred to as a first hole transport layer), an electron barrier layer (EBL) 263, an organic emission layer (EML) 264A (or referred to as a first organic emission layer), an electron transport layer (ETL) 265 (or referred to as a first electron transport layer), and an electron injection layer (EIL) 266. In some embodiments, the electrode 218 is above the organic light emitting layer 260A.

As shown in FIG. 2B, in some embodiments, the organic light emitting unit 102 includes the electrode 225 (or referred to as the second electrode), the organic light emitting layer 260B, and the electrode 218 (or referred to as the top electrode or the common electrode). In some embodiments, the organic light emitting layer 260B includes a plurality of organic material layers, for example, a hole injection layer (HIL) 261, a hole transport layer (HTL) 262 (or referred to as a second hole transport layer), an electron barrier layer (EBL) 263, an organic emission layer (EML) 264B (or referred to as a second organic emission layer), a hole barrier layer (HBL) 267, an electron transport layer (ETL) 265 (or referred to as a second electron transport layer), and an electron injection layer (EIL) 266. In some embodiments, the electrode 218 is above the organic light emitting layer 260B.

As shown in FIG. 2C, in some embodiments, the organic light emitting unit 103 includes the electrode 235 (or referred to as the third electrode), the organic light emitting layer 260C, and the electrode 218 (or referred to as the top electrode or the common electrode). In some embodiments, the organic light emitting layer 260C includes a plurality of organic material layers, for example, a hole injection layer (HIL) 261, a hole transport layer (HTL) 262 (or referred to as a third hole transport layer), an electron barrier layer (EBL) 263, an organic emission layer (EML) 264C (or referred to as a third organic emission layer), an electron transport layer (ETL) 265 (or referred to as a third electron transport layer), and an electron injection layer (EIL) 266. In some embodiments, the electrode 218 is above the organic light emitting layer 260C.

In some embodiments, an edge E11 of the hole transport layer 262 of the organic light emitting layer 260A and an edge E12 opposite to the edge E11 are above the spacer structure 30 and are at different elevations. The edge E11 is at an elevation H11, and the edge E12 is at an elevation H12. In some embodiments, an edge E21 of the hole transport layer 262 of the organic light emitting layer 260B and an edge E22 opposite to the edge E21 are above the spacer structure 30 and are at different elevations. The edge E21 is at an elevation H21, and the edge E22 is at an elevation H22. In some embodiments, an edge E31 of the hole transport layer 262 of the organic light emitting layer 260C and an edge E32 opposite to the edge E31 are above the spacer structure 30 and are at substantially the same elevation. The edge E31 is at an elevation H31, and the edge E32 is at an elevation H32.

In some embodiments, the edge E11 of the hole transport layer 262 of the organic light emitting layer 260A is closer to the organic light emitting layer 260B than the edge E12, and the elevation H11 of the edge E11 is higher than the elevation H12 of the edge E12.

In some embodiments, all of the hole transport layer 262 of the organic light emitting layer 260A, the hole transport layer 262 of the organic light emitting layer 260B and the hole transport layer 262 of the organic light emitting layer 260C partially cover the spacer structure 30. In some embodiments, an extension length L1 of the hole transport layer 262 of the organic light emitting layer 260B on the spacer structure 30 is greater than an extension length L2 of the hole transport layer 262 of the organic light emitting layer 260A on the spacer structure 30. In some embodiments, an extension length L3 of the hole transport layer 262 of the organic light emitting layer 260B on the spacer structure 30 is greater than an extension length L4 of the hole transport layer 262 of the organic light emitting layer 260C on the spacer structure 30.

In some embodiments, a thickness T22 of the hole transport layer 262 of the organic light emitting layer 260B is greater than a thickness T12 of the hole transport layer 262 of the organic light emitting layer 260A, and the thickness T12 of the hole transport layer 262 of the organic light emitting layer 260A is greater than a thickness T32 of the hole transport layer 262 of the organic light emitting layer 260C. In some embodiments, an elevation of an upper surface of the hole transport layer 262 of the organic light emitting layer 260B is higher than an elevation of an upper surface of the hole transport layer 262 of the organic light emitting layer 260A. In some embodiments, the elevation of the upper surface of the hole transport layer 262 of the organic light emitting layer 260B is higher than an elevation of an upper surface of the hole transport layer 262 of the organic light emitting layer 260C.

In some embodiments, a thickness T24 of the organic emission layer 264B is greater than a thickness T14 of the organic emission layer 264A, and the thickness T14 of the organic emission layer 264A is greater than a thickness T34 of the organic emission layer 264C. In some embodiments, a thickness T25 of the electron transport layer 265 of the organic light emitting layer 260B is greater than a thickness T15 of the electron transport layer 265 of the organic light emitting layer 260A and greater than a thickness T35 of the electron transport layer 265 of the organic light emitting layer 260C.

In some embodiments, the electrode 218 (or referred to as the top electrode or the common electrode) includes an electrode layer 216 and a conductivity enhancer 217. In some embodiments, the electrode layer 216 is over the organic light emitting layers 260A, 260B and 260C, and the conductivity enhancer 217 at least partially covers the electrode layer 216. In some embodiments, as shown in FIG. 2, the conductivity enhancer 217 substantially completely covers the electrode layer 216. In some embodiments, the electrode 218 is a cathode. In some embodiments, the electrode 218 is a common electrode of a plurality of organic light emitting units. In some embodiments, the electrode 218 is a common electrode of all light emitting pixels in the light emitting layer 20. In some embodiments, the electrode 218 is a common electrode of all organic light emitting units in the organic light emitting element 10.

In some embodiments, the electrode layer 216 contacts the organic light emitting layers 260A, 260B and 260C. The electrode layer 216 may be a continuous film as shown in FIG. 2 and above the organic light emitting layers 260A, 260B and 260C and the protrusions 310. In some embodiments, the electrode layer 216 may be over the spacer structure 30. In some embodiments, the electrode layer 216 is a common electrode of all light emitting pixels in the light emitting layer 20. In some embodiments, the electrode layer 216 includes a metal material, for example, Ag, Al, Mg, Au, AlCu alloy or AgMo alloy. In some embodiments, the electrode layer 216 includes ITO or other appropriate materials.

In some embodiments, the conductivity enhancer 217 directly contacts the electrode layer 216. The conductivity enhancer 217 may be a continuous film as shown in FIG. 2 and over the electrode layer 216. In some embodiments, the thickness T2 of the organic light emitting layer 260B is greater than the thickness T1 of the organic light emitting layer 260A and the thickness T3 of the organic light emitting layer 260C, and the conductivity enhancer 217 contacts and covers the electrode layer 216 over the organic light emitting layer 260B. In some embodiments, the conductivity enhancer 217 has an upper surface 217a2 and a lower surface 217b2 at a portion above the organic light emitting layer 260B, and the conductivity enhancer 217 has an upper surface 217a1 and a lower surface 217b1 at a portion above the organic light emitting layer 260A. In some embodiments, an elevation of the lower surface 217b2 of the conductivity enhancer 217 at the portion above the organic light emitting layer 260B is higher than an elevation of the upper surface 217a1 of the conductivity enhancer 217 at the portion above the organic light emitting layer 260A. In some embodiments, the conductivity enhancer 217 is at least partially above the protrusion 310 (or referred to as an insulating protrusion).

In some embodiments, the conductivity enhancer 217 includes a metal material, and the metal material of the conductivity enhancer 217 may be different from the metal material of the electrode layer 216. In some embodiments, the conductivity enhancer 217 includes a transparent conductive material. In some embodiments, the transparent conductive material includes a conductive metal oxide. In some embodiments, a compressive strength of the conductivity enhancer 217 or the metal material of the conductivity enhancer 217 is greater than a compressive strength of the electrode layer 216 or the metal material of the electrode layer 216. In some embodiments, the electrode layer 216 includes a silver layer, and the conductivity enhancer 217 includes an indium zinc oxide (IZO) layer. In some embodiments, as shown in FIG. 2A, FIG. 2B and FIG. 2C, a thickness T217 of the conductivity enhancer 217 is less than or equal to a thickness T216 of the electrode layer 216. In some embodiments, the thickness T217 of the conductivity enhancer 217 may also be greater than the thickness T216 of the electrode layer 216.

In some embodiments, the spacer structure 30 is on the substrate 100 and partially covers the electrodes 215, 225 and 235. In some embodiments, the spacer structure 30 is located among the organic light emitting layers 260A, 260B and 260C. In some embodiments, the spacer structure 30 may include protrusions 310. In some embodiments, a pattern of the spacer structure 30 is designed according to a pixel layout. In some embodiments, the spacer structure 30 serves as a pixel defined layer (PDL). In some embodiments, the protrusions 310 define a pixel region. In some embodiments, each protrusion 310 fills a gap between two adjacent ones of the electrodes 215, 225 and 235. Each of the electrodes 215, 225 and 235 is partially covered by the protrusion 310. In some embodiments, the spacer structure 30 includes an organic insulating material. In some embodiments, the spacer structure 30 includes a photosensitive material. In some embodiments, the spacer structure 30 may further include quantum dots, which have excellent light absorption performance. In some embodiments, the spacer structure 30 may further include a carbon black material, for example, carbon black nanoparticles, conductive fibers containing carbon black, or the like. In some embodiments, the spacer structure 30 may further include a black body material, which has an absorption rate of more than 90%, 95%, 99%, 99.5% or 99.9% for visible light.

In some embodiments, the spacer structure 30 has an absorption rate of greater than or equal to 50% for a specific wavelength. In some embodiments, the spacer structure 30 has an absorption rate of greater than or equal to 60% for a specific wavelength. In some embodiments, the spacer structure 30 has an absorption rate of greater than or equal to 70% for a specific wavelength. In some embodiments, the spacer structure 30 has an absorption rate of greater than or equal to 80% for a specific wavelength. In some embodiments, the spacer structure 30 has an absorption rate of greater than or equal to 90% for a specific wavelength. In some embodiments, the spacer structure 30 has an absorption rate of greater than or equal to 95% for a specific wavelength. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150nm. In some embodiments, the specific wavelength is not greater than 100 nm.

In some embodiments, a vertical distance D1 between the elevation of the upper surface of the hole transport layer 262 of the organic light emitting layer 260B and an elevation of an upper surface of the spacer structure 30 is less than a vertical distance D2 between the elevation of the upper surface of the hole transport layer 262 of the organic light emitting layer 260A and the elevation of the upper surface of the spacer structure 30. In some embodiments, the vertical distance D2 between the elevation of the upper surface of the hole transport layer 262 of the organic light emitting layer 260A and the elevation of an upper surface of the spacer structure 30 is less than a vertical distance D3 between the elevation of the upper surface of the hole transport layer 262 of the organic light emitting layer 260C and the elevation of the upper surface of the spacer structure 30.

In some embodiments, the cover layer 40 includes a capping layer 410, an encapsulation layer 420, a filler layer 430 and a cover plate 440. In some embodiments, the capping layer 410 is disposed above the electrode 218, and is substantially conformal with a non-flat upper surface of the electrode 218. In some embodiments, the capping layer 410 directs contacts the conductivity enhancer 217, and is substantially conformal with a non-flat upper surface of the conductivity enhancer 217. The capping layer 410 may include a dielectric material or an inorganic insulating material, for example, SiO2.

In some embodiments, the encapsulation layer 420 is disposed over the capping layer 410, and is substantially conformal with a non-flat upper surface of the capping layer 410. The encapsulation layer 420 may include an oxide, for example, SiO2. In some embodiments, the encapsulation layer 420 is substantially conformal with the non-flat upper surface of the capping layer 410, and includes a plurality of recesses corresponding to the organic light emitting layers 260A, 260B and 260C. In some embodiments, the plurality of recesses of the encapsulation layer 420 are at different elevations H1, H2 and H3. In some embodiments, the elevation H2 is higher than the elevation H1, and the elevation H1 is higher than the elevation H3.

In some embodiments, the filler layer 430 is disposed over the encapsulation layer 420, and a lower surface of the filler layer 430 is substantially conformal with a non-flat upper surface of the encapsulation layer 420. The filler layer 430 may also be referred to as a flat layer. In some embodiments, the cover plate 440 is disposed over a flat upper surface of the filler layer 430. The cover plate 440 may also be referred to as a protective layer. The cover plate 440 may include a transparent hard cover plate, for example, a glass plate.

In some embodiments, when the thickness T2 of the organic light emitting layer 260B is greater than the thickness T1 of the organic light emitting layer 260A and the thickness T3 of the organic light emitting layer 260C, the organic light emitting layer 260B is more protruding from an upper surface of the entire light emitting layer 20. As a result, the cover layer 40 above the organic light emitting layer 260B may impose a relatively large stress upon a partial region above the organic light emitting layer 260B, and the electrode 218 above the organic light emitting layer 260B is then subject to pressing between the cover layer 40 and the organic light emitting layer 260B and bear a relatively large stress. In some embodiments, when the luminescence wavelength of the organic light emitting layer 260B is greater than the luminescence wavelength of the organic light emitting layer 260A, and the thickness T2 of the organic light emitting layer 260B is adjusted to be close to the thickness T1 of the organic light emitting layer 206A and the thickness T3 of the organic light emitting layer 260C with the aim of overcoming the issue above, the thickness T2 of the organic light emitting layer 260B after such adjustment or the thickness T1 of the organic light emitting layer 260A may fail to provide a good microcavity structure for the corresponding luminescence wavelengths, rendering light emitting luminance or chrominance of the organic light emitting element to be less than expected.

According to some embodiments of the present disclosure, the conductivity enhancer 217 is disposed above the electrode layer 216, and the conductivity enhancer 217 has a better compressive strength compared with the electrode layer 216. That is to say, despite that in order to achieve good luminescence performance, the thickness T2 of the organic light emitting layer 260B is designed to be greater than the thickness T1 of the organic light emitting layer 260A and/or the thickness T3 of the organic light emitting layer 260C, and the organic light emitting layer 260B is thus made to be more protruding from the upper surface of the entire light emitting layer 20. However, the conductivity enhancer 217 can provide the structure of the electrode layer 216 with protection and reinforcement and effectively prevent the electrode layer 216 from disconnection caused by pressing and stress. Therefore, in addition to maintaining the thickness design of the organic light emitting layer of the organic light emitting element 10 and providing the organic light emitting element 10 with good luminance and extremely small color shift in CIE 1931 coordinates, the electrode 218 can be effectively prevented from disconnection caused by pressing and stress, thereby improving reliability and luminescence performance of the organic light emitting element 10.

In addition, according to some embodiments of the present disclosure, the conductivity enhancer 217 substantially completely covers the electrode layer 216. As such, the electrode layer 216 is further comprehensively protected, and the electrode layer 216 is substantially free of any region that is not covered by the conductivity enhancer 217. Thus, the electrode 218 in its entirety has a rather uniform compressive strength without any structural weakness, further better effectively preventing the electrode layer 216 or the electrode 218 from disconnection caused by pressing and stress, and improving reliability and luminescence performance of the organic light emitting element 10.

Moreover, according to some embodiments of the present disclosure, the conductivity enhancer 217 includes a metal material having a greater compressive strength and substantially completely covers and directly contacts the electrode layer 216. Since the metal material of the conductivity enhancer 217 completely covers and directs contacts the electrode layer 216, the conductivity enhancer 217 and the electrode layer 216 have a good bonding strength in between. Therefore, the metal material having a high compressive strength of the conductivity enhancer 217 is able to more effectively and more comprehensively provide the electrode layer 216 with structural support and reinforcement, further better effectively preventing the electrode layer 216 or the electrode 218 from disconnection caused by pressing and stress, and improving reliability and luminescence performance of the organic light emitting element 10.

Furthermore, according to some embodiments of the present disclosure, by configuring the elevation H11 of the edge E11 to be higher than the elevation H12 of the edge E12, a step difference between the organic light emitting layer 260B and the protrusion 310 and a step difference between the protrusion 310 and the organic light emitting layer 260A can be reduced, such that an entire upper surface of the organic light emitting layer 260B extending to the organic light emitting layer 260A via the protrusion 310 appears more moderate to further alleviate a level of bulging of the protrusion 310, and as a result, the protrusion 310 does not overly protrude from the upper surface of the entire light emitting layer 20. Thus, with the configuration of the elevation H11 of the edge E11 higher than the elevation H12 of the edge E12 in combination with the design of the conductivity enhancer 217, stress brought by the encapsulation layer 420 above the protrusion 310 upon the partial region over the protrusion 310 can be reduced, thereby effectively preventing the electrode layer 216 or the electrode 218 above the protrusion 310 from disconnection owing to the stress brought by pressing between the encapsulation layer 420 and the protrusion 310.

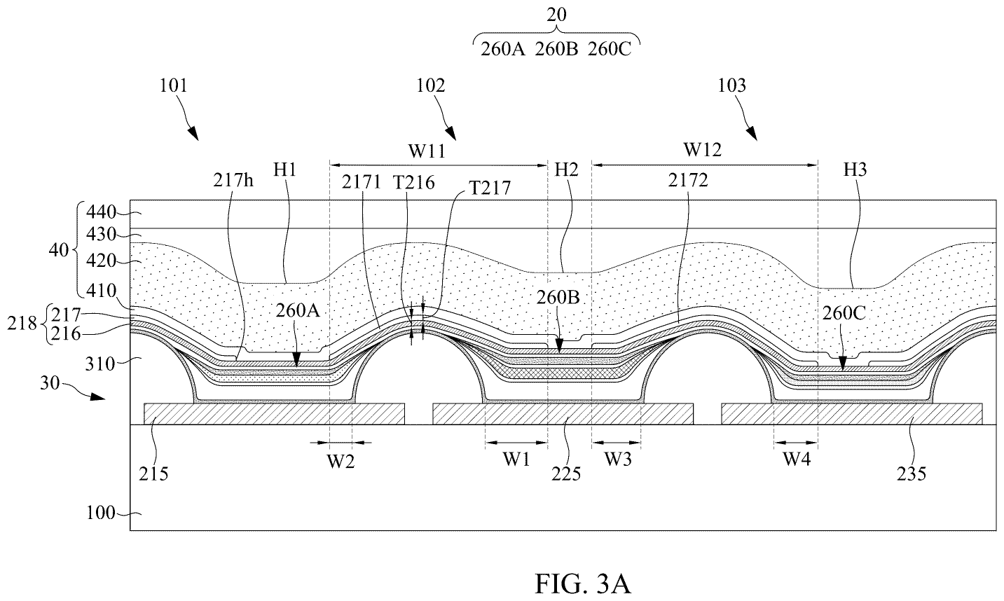

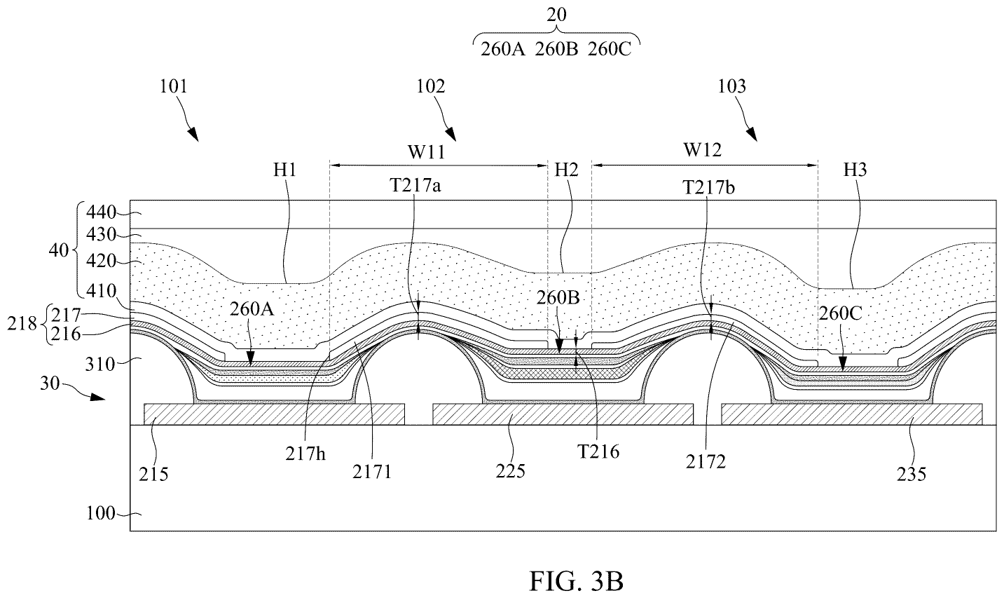

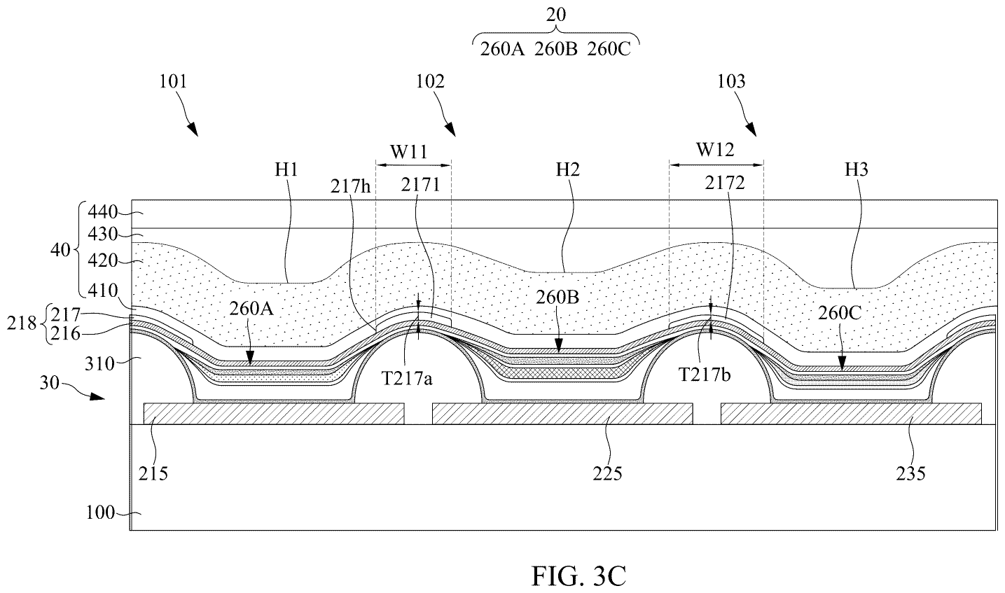

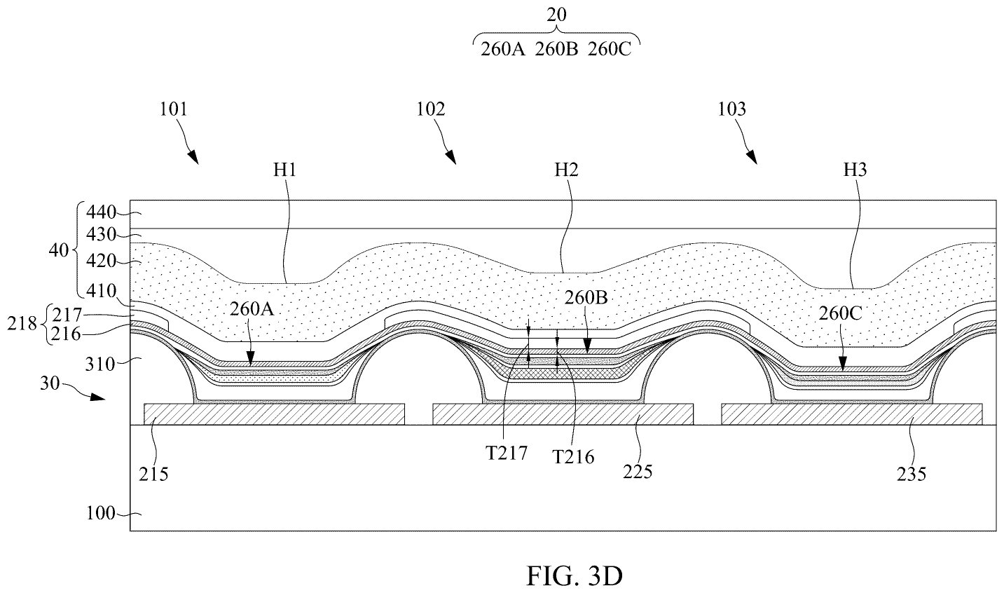

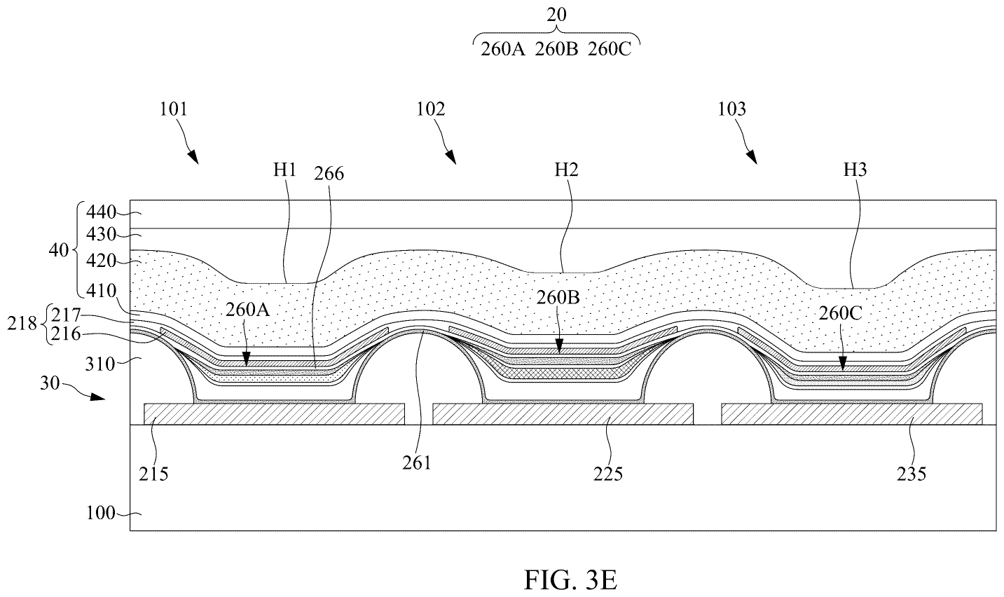

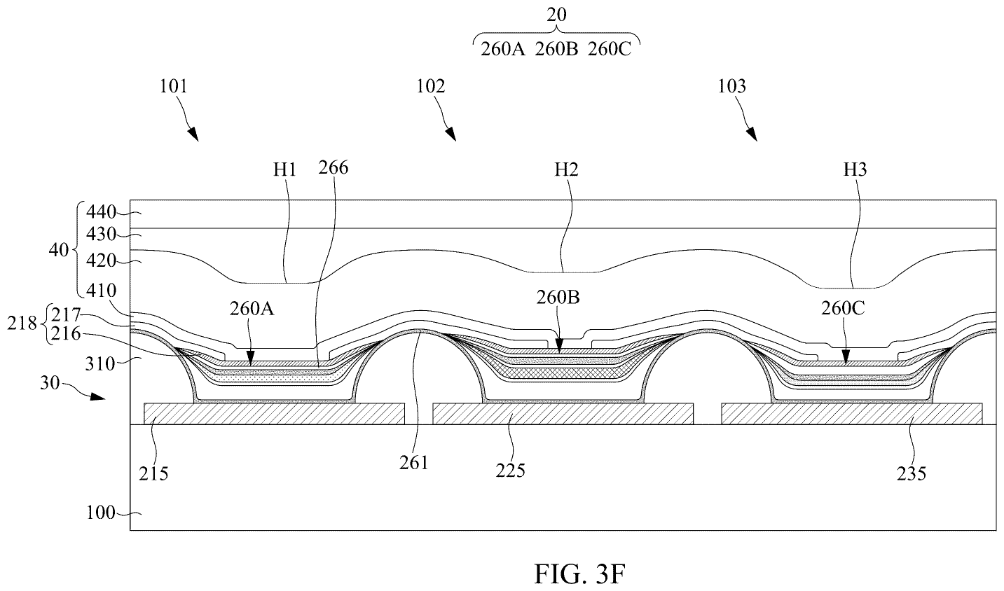

FIG. 3A shows a cross-sectional diagram taken along the line A-A′ in FIG. 1 according to some embodiments. In some embodiments, FIG. 3A shows a cross-sectional diagram taken along the line A-A′ in FIG. 1 as an example, and only a light emitting region is illustrated. The structure in FIG. 3A is similar to the structure in FIG. 2, and differences therebetween are described below.

In some embodiments, each of the organic light emitting layers 260A, 260B and 260C is in a recess between two adjacent ones of the protrusions 310 (or referred to as the insulating protrusions), and the conductivity enhancer 217 is at least partially above the protrusion 310. In some embodiments, the conductivity enhancer 217 is at least partially not located above the organic light emitting layers 260A, 260B and 260C. In some embodiments, the conductivity enhancer 217 defines a plurality of openings 217h exposing the organic light emitting layers 260A, 260B and 260C. In some embodiments, the openings 217h above the individual organic light emitting layers 260A, 260B and 260C may have different sizes (for example, different widths). In some embodiments, from a cross-sectional view perspective, the conductivity enhancer 217 includes a plurality of sections (for example, conductivity enhancing sections 2171 and 2172) separated from one another, and each of the sections covers each of the protrusions 310.

In some embodiments, from a cross-sectional view perspective, the conductivity enhancing sections may have different widths. In some embodiments, a width W11 of the conductivity enhancing section 2171 is less than a width W12 of the conductivity enhancing section 2172. In some embodiments, from a cross-sectional view perspective, an extension length W1 of the conductivity enhancing section 2171 over the organic light emitting layer 260B is greater than an extension length W2 of the conductivity enhancing section 2171 over the organic light emitting layer 260A. In some embodiments, from a cross-sectional view perspective, an extension length W3 of the conductivity enhancing section 2172 over the organic light emitting layer 260B is greater than an extension length W4 of the conductivity enhancing section 2172 over the organic light emitting layer 260C. In some embodiments, from a cross-sectional view perspective, the extension length W1 is greater than the extension length W3.

According to some embodiments of the present disclosure, each of the sections of the conductivity enhancer 217 covers each of the protrusions 310 protruding from the upper surface of the entire light emitting layer 20, and thus the conductivity enhancer 217 can provide protection and reinforcement especially for the structure of the electrode layer 216 above the protrusions 310 and effectively prevent the electrode layer 216 above the protrusions 310 from disconnection caused by pressing and stress. Thus, in addition to maintaining the thickness design of the organic light emitting layer of the organic light emitting element 10 and providing the organic light emitting element 10 with good luminance and extremely small color shift in CIE 1931 coordinates, the electrode 218 can be effectively prevented from disconnection caused by pressing and stress, thereby improving reliability and luminescence performance of the organic light emitting element 10.

Moreover, according to some embodiments of the present disclosure, with the design of the different extension lengths of the individual conductivity enhancing sections over the individual organic light emitting layers, the electrode layer above the organic light emitting layer that is more protruding with reinforced protection (for example, the extension length of the conductivity enhancing section above the more protruding organic light emitting layer 260B is longer). Thus, pressure protection can be more effectively provided for a region that is more susceptible to severer pressing and higher stress, further preventing the electrode 218 from disconnection caused by pressing and stress and improving reliability and luminescence performance of the organic light emitting element 10.

FIG. 3B shows a cross-sectional diagram taken along the line A-A′ in FIG. 1 according to some embodiments. In some embodiments, FIG. 3B shows a cross-sectional diagram taken along the line A-A′ in FIG. 1 as an example, and only a light emitting region is illustrated. The structure in FIG. 3B is similar to the structure in FIG. 2, and differences therebetween are described below.

In some embodiments, the thickness of the conductivity enhancer 217 is greater than the thickness of the electrode layer 216. In some embodiments, a thickness T217a of the conductivity enhancing section 2171 is greater than the thickness T216 of the electrode layer 216. In some embodiments, a thickness T217b of the conductivity enhancing section 2172 is greater than the thickness T216 of the electrode layer 216. In some embodiments, the width W11 of the conductivity enhancing section 2171 is greater than the width W12 of the conductivity enhancing section 2172.

According to some embodiments of the present disclosure, with the thickness of the conductivity enhancer 217 greater than the thickness of the electrode layer 216 in combination with the design of the organic light emitting layer at least partially exposed from the openings of the conductivity enhancer 217, in addition to effectively preventing the electrode layer 216 or the electrode 218 above the protrusions from disconnection, a dielectric material above a light emitting region can be reduced to further improve luminescence intensity and luminescence performance.

FIG. 3C shows a cross-sectional diagram taken along the line A-A′ in FIG. 1 according to some embodiments. In some embodiments, FIG. 3C shows a cross-sectional diagram taken along the line A-A′ in FIG. 1 as an example, and only a light emitting region is illustrated. The structure in FIG. 3C is similar to the structure in FIG. 2, and differences therebetween are described below.

In some embodiments, the conductivity enhancer 217 includes different portions covering different protrusions, for example, a first portion (that is, the conductivity enhancing section 2171) and a second portion (that is, the conductivity enhancing section 2172), and the two portions have different thicknesses. In some embodiments, the thickness T217a of the conductivity enhancing section 2171 is greater than the thickness T217b of the conductivity enhancing section 2172. In some embodiments, the conductivity enhancer 217 merely covers the protrusions 310, and the conductivity enhancer 217 does not extend to or cover above the light emitting regions of the organic light emitting layers 260A, 260B and 260C.

According to some embodiments of the present disclosure, by designing different conductivity enhancing sections above different protrusions to have different thicknesses, different stress imposed upon the different protrusions having different heights can be further compensated, so that the conductivity enhancing sections can more effectively prevent the electrode layer 216 or the electrode 218 above the protrusions from disconnection.

FIG. 3D shows a cross-sectional diagram taken along the line A-A′ in FIG. 1 according to some embodiments. In some embodiments, FIG. 3D shows a cross-sectional diagram taken along the line A-A′ in FIG. 1 as an example, and only a light emitting region is illustrated. The structure in FIG. 3D is similar to the structure in FIG. 2, and differences therebetween are described below.

In some embodiments, the conductivity enhancing section 2171 of the conductivity enhancer 217 partially covers the organic light emitting layer 260B that is more protruding from the upper surface of the entire light emitting layer 20. In some embodiments, the openings 217h of the conductivity enhancer 217 expose the remaining organic light emitting layers 260A and 260C. In some embodiments, both of the light emitting region of the organic light emitting layer 260A and the light emitting region of the organic light emitting layer 260C are substantially completely exposed from the openings 217h of the conductivity enhancer 217. In some embodiments, the thickness T217 of the conductivity enhancer 217 is greater than the thickness T216 of the electrode layer 216.

According to some embodiments of the present disclosure, the conductivity enhancing sections partially cover the organic light emitting layer 260B that is more protruding from the upper surface of the entire light emitting layer 20 and expose the remaining organic light emitting layers 260A and 260C, such that protection provided for the electrode layer 216 by the conductivity enhancer 217 can be locally reinforced, and the dielectric material above the light emitting region can be reduced as much as possible to further improve luminescence intensity and luminescence performance.

FIG. 3E shows a cross-sectional diagram taken along the line A-A′ in FIG. 1 according to some embodiments. In some embodiments, FIG. 3E shows a cross-sectional diagram taken along the line A-A′ in FIG. 1 as an example, and only a light emitting region is illustrated. The structure in FIG. 3E is similar to the structure in FIG. 2, and differences therebetween are described below.

In some embodiments, the electrode layer 216 is at least partially not located at a top portion of the protrusion 310. In some embodiments, the electrode layer 216 includes a plurality of electrode portions separated from one another and respectively located above the organic light emitting layers 260A, 260B and 260C. In some embodiments, the conductivity enhancer 217 substantially completely covers the electrode layer 216 and contacts the organic light emitting layers 260A, 260B and 260C (or an electron injection layer 266) above the protrusions 310. In some embodiments, the thickness of the conductivity enhancer 217 is greater than the thickness of the electrode layer 216.

According to some embodiments of the present disclosure, the plurality of electrode portions of the electrode layer 216 are respectively located over the organic light emitting layers 260A, 260B and 260C, and thus heights above recesses between the adjacent protrusions 310 can be elevated to further reduce height differences between the protrusions and light emitting pixels. Moreover, since the conductivity enhancer 217 in a greater thickness substantially completely covers the electrode layer 216, the electrode 218 in its entirety has a rather uniform compressive strength without any structural weakness, further better effectively preventing the electrode layer 216 or the electrode 218 from disconnection caused by pressing and stress, and improving reliability and luminescence performance of the organic light emitting element 10.

FIG. 3F shows a cross-sectional diagram taken along the line A-A′ in FIG. 1 according to some embodiments. In some embodiments, FIG. 3F shows a cross-sectional diagram taken along the line A-A′ in FIG. 1 as an example, and only a light emitting region is illustrated. The structure in FIG. 3F is similar to the structure in FIG. 2, and differences therebetween are described below.

In some embodiments, the electrode layer 216 is at least partially not located at a top portion of the protrusion 310. In some embodiments, the electrode layer 216 includes a plurality of electrode portions separated from one another and respectively located above the organic light emitting layers 260A, 260B and 260C. In some embodiments, the conductivity enhancer 217 is at least partially above the protrusion 310. In some embodiments, the conductivity enhancer 217 is at least partially not located above the organic light emitting layers 260A, 260B and 260C.

According to some embodiments of the present disclosure, the conductivity enhancer 217 is at least partially above the protrusions 310 and is connected to the electrode layer 216 above each of the organic light emitting layers 260A, 260B and 260C. Thus, the conductivity enhancer 217 allows the individual portions of the electrode layer 216 to be electrically connected to one another, and the conductivity enhancer 217 is in a region more susceptible to severer pressing and higher stress so as to provide pressure protection, further preventing the electrode 218 from disconnection caused by pressing and stress and improving reliability and luminescence performance of the organic light emitting element 10.

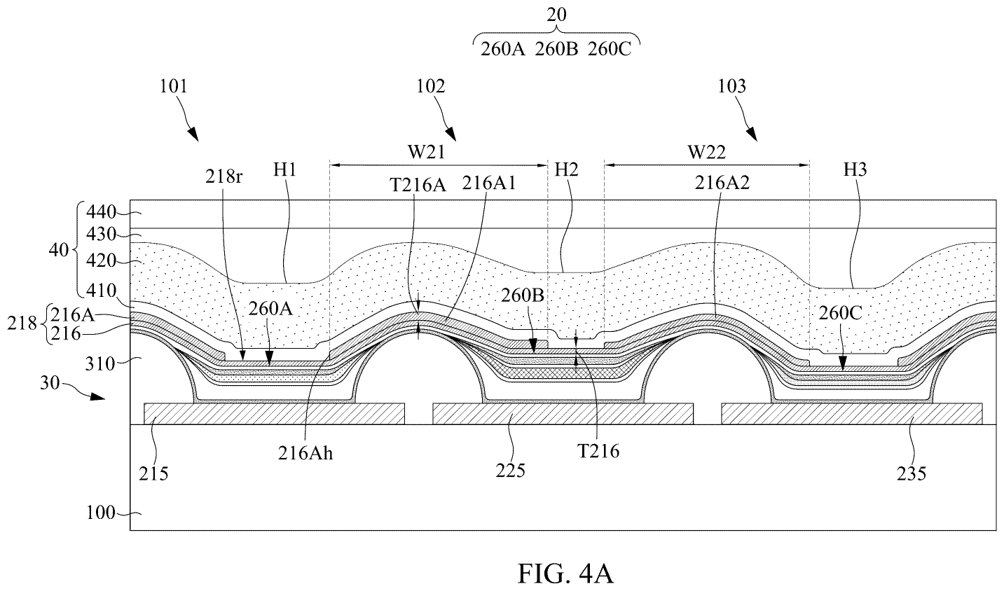

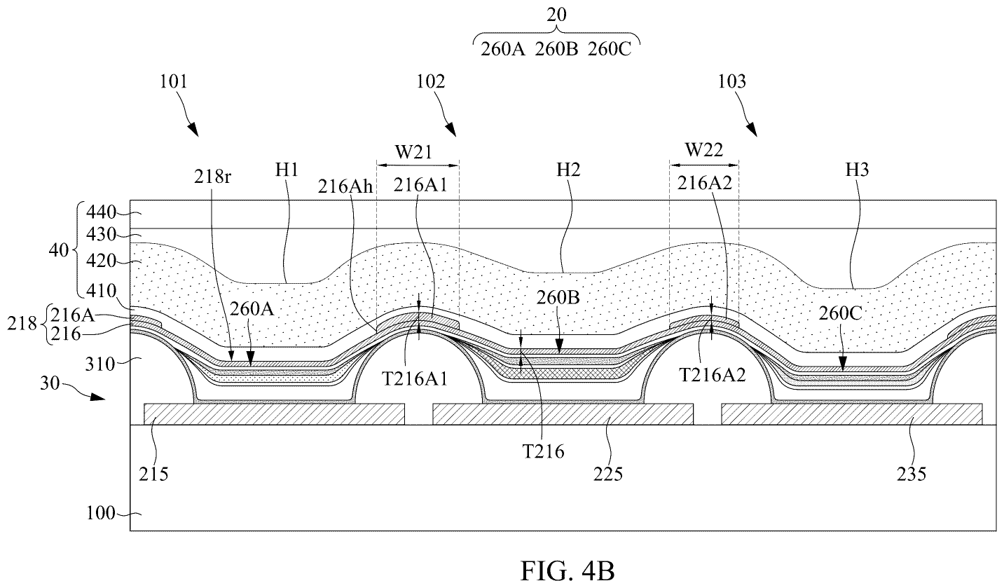

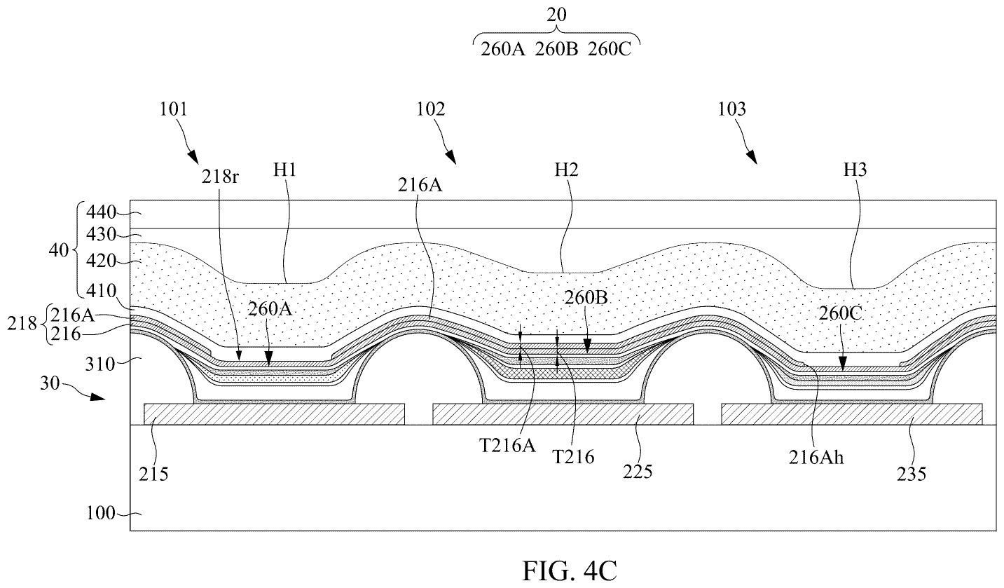

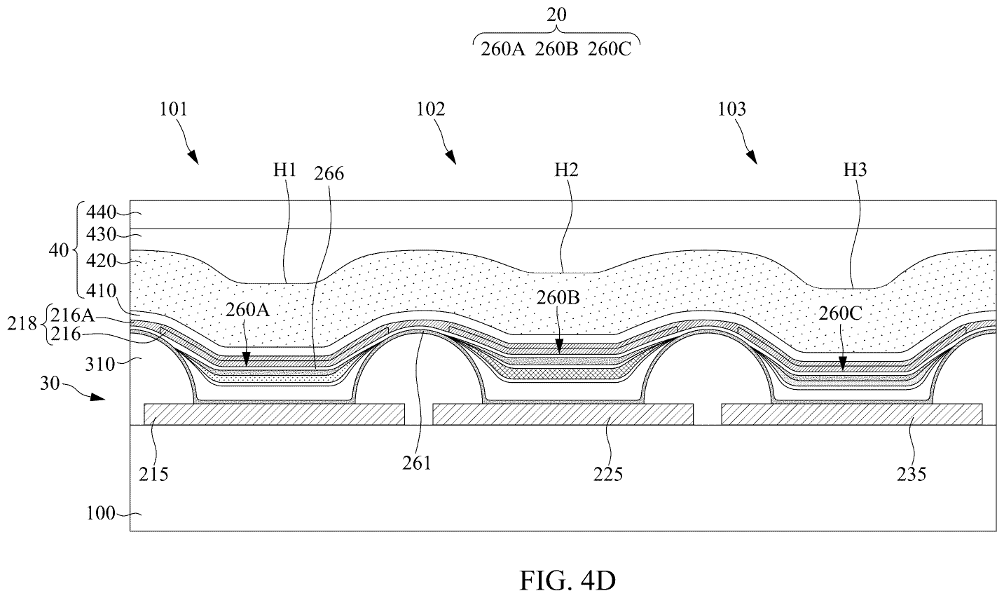

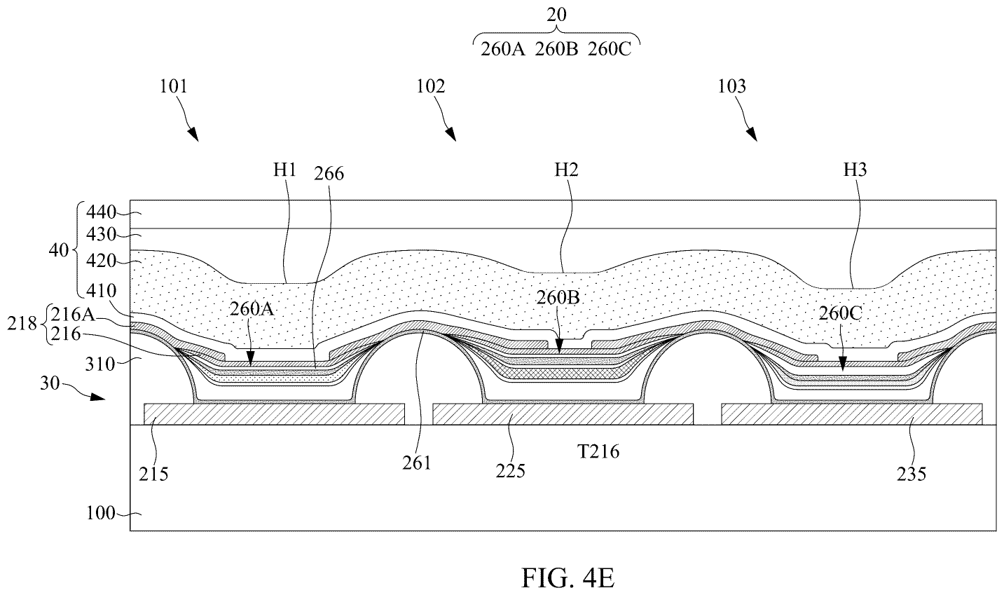

FIG. 4A shows a cross-sectional diagram taken along the line A-A′ in FIG. 1 according to some embodiments. In some embodiments, FIG. 4A shows a cross-sectional diagram taken along the line A-A′ in FIG. 1 as an example, and only a light emitting region is illustrated. The structure in FIG. 4A is similar to the structure in FIG. 2, and differences therebetween are described below.

In some embodiments, the electrode 218 includes an electrode layer 216 and a conductivity enhancer 216A, wherein the electrode layer 216 and the conductivity enhancer 216A include the same metal material. In some embodiments, the electrode layer 216 and the conductive enhancer 216A include Ag or are made of Ag.

In some embodiments, the conductivity enhancer 216A is at least partially above the protrusions 310. In some embodiments, the conductivity enhancer 216A is at least partially not located above the organic light emitting layers 260A, 260B and 260C. In some embodiments, the conductivity enhancer 216A defines a plurality of openings 216Ah exposing the organic light emitting layers 260A, 260B and 260C. In some embodiments, the openings 216Ah above the individual organic light emitting layers 260A, 260B and 260C may have different sizes (for example, different widths). In some embodiments, a thickness T216A of the conductivity enhancer 216A is greater than a thickness T216 of the electrode layer 216.

In some embodiments, from a cross-sectional view perspective, the conductivity enhancer 216A includes a plurality of sections (for example, conductivity enhancing sections 216A1 and 216A2) separated from one another, and each of the sections covers each of the protrusions 310. In some embodiments, from a cross-sectional view perspective, the conductivity enhancing sections may have different widths. In some embodiments, a width W21 of the conductivity enhancing section 216A1 is greater than a width W22 of the conductivity enhancing section 216A2. In some embodiments, the electrode layer 216 and the conductivity enhancer 216A are made of the same metal material, and it is possible that the two do not have a perceptible interface in between. Thus, the electrode 218 formed thereby has a single-piece or monolithic structure formed by the electrode layer 216 and the conductivity enhancer 216A, and has recesses 218r defined by the electrode layer 216 and the conductivity enhancer 216A. In some embodiments, the individual recesses 218r are respectively located above the organic light emitting layers 260A, 260B and 260C.

According to some embodiments of the present disclosure, the electrode layer 216 and the conductivity enhancer 216A include the same metal material or are made of the same metal material, and the two are homogeneously bonded and thus have a higher bonding strength in between. Therefore, the conductivity enhancer 216A is able to more effectively and more comprehensively provide the electrode layer 216 with the auxiliary for structural support and reinforcement, or even the electrode 218 may be formed in a single-piece or monolithic structure having a higher compressive strength, further better effectively preventing the electrode layer 216 or the electrode 218 from disconnection caused by pressing and stress, and improving reliability and luminescence performance of the organic light emitting element 10.

FIG. 4B shows a cross-sectional diagram taken along the line A-A′ in FIG. 1 according to some embodiments. In some embodiments, FIG. 4B shows a cross-sectional diagram taken along the line A-A′ in FIG. 1 as an example, and only a light emitting region is illustrated. The structure in FIG. 4B is similar to the structure in FIG. 2, and differences therebetween are described below.

In some embodiments, the conductivity enhancer 216A merely covers the protrusions 310, and the conductivity enhancer 216A does not extend over or cover the light emitting regions of the organic light emitting layers 260A, 260B and 260C. In some embodiments, a width W21 of the conductivity enhancing section 216A1 is greater than a width W22 of the conductivity enhancing section 216A2. In some embodiments, the thickness T216A of the conductivity enhancer 216A is greater than the thickness T216 of the electrode layer 216. In some embodiments, a thickness T216A1 of the conductivity enhancing section 216A1 is greater than a thickness T216A2 of the conductivity enhancing section 216A2.

FIG. 4C shows a cross-sectional diagram taken along the line A-A′ in FIG. 1 according to some embodiments. In some embodiments, FIG. 4C shows a cross-sectional diagram taken along the line A-A′ in FIG. 1 as an example, and only a light emitting region is illustrated. The structure in FIG. 4C is similar to the structure in FIG. 2, and differences therebetween are described below.

In some embodiments, the conductivity enhancer 216A is at least partially above the organic light emitting layer 260B. In some embodiments, the conductivity enhancer 216A is at least partially not located above the organic light emitting layers 260A and 260C. In some embodiments, the thickness T216A of the conductivity enhancer 216A is substantially equal to the thickness T216 of the electrode layer 216.

FIG. 4D shows a cross-sectional diagram taken along the line A-A′ in FIG. 1 according to some embodiments. In some embodiments, FIG. 4D shows a cross-sectional diagram taken along the line A-A′ in FIG. 1 as an example, and only a light emitting region is illustrated. The structure in FIG. 4D is similar to the structure in FIG. 2, and differences therebetween are described below.

In some embodiments, the electrode layer 216 is at least partially not located at a top portion of the protrusion 310. In some embodiments, the electrode layer 216 includes a plurality of electrode portions separated from one another and respectively located above the organic light emitting layers 260A, 260B and 260C. In some embodiments, the conductivity enhancer 216A substantially completely covers the electrode layer 216 and contacts the organic light emitting layers 260A, 260B and 260C (or an electron injection layer 266) above the protrusions 310.

According to some embodiments of the present disclosure, the plurality of electrode portions of the electrode layer 216 are respectively located over the organic light emitting layers 260A, 260B and 260C, and thus heights above recesses between the adjacent protrusions 310 can be elevated to further reduce height differences between the protrusions and light emitting pixels. Moreover, since the conductivity enhancer 216A substantially completely covers the electrode layer 216, the electrode 218 in its entirety has a rather uniform compressive strength without any structural weakness, further better effectively preventing the electrode layer 216 or the electrode 218 from disconnection caused by pressing and stress, and improving reliability and luminescence performance of the organic light emitting element 10.

FIG. 4E shows a cross-sectional diagram taken along the line A-A′ in FIG. 1 according to some embodiments. In some embodiments, FIG. 4E shows a cross-sectional diagram taken along the line A-A′ in FIG. 1 as an example, and only a light emitting region is illustrated. The structure in FIG. 4E is similar to the structure in FIG. 2, and differences therebetween are described below.

In some embodiments, the electrode layer 216 is at least partially not located at a top portion of the protrusion 310. In some embodiments, the electrode layer 216 includes a plurality of electrode portions separated from one another and respectively located above the organic light emitting layers 260A, 260B and 260C. In some embodiments, the conductivity enhancer 216A is at least partially above the protrusions 310. In some embodiments, the conductivity enhancer 216A is at least partially not located above the organic light emitting layers 260A, 260B and 260C.

According to some embodiments of the present disclosure, the conductivity enhancer 216A is at least partially above the protrusions 310, and is connected to the electrode layer 216 above the organic light emitting layers 260A, 260B and 260C. Thus, the conductivity enhancer 216A allows the individual portions of the electrode layer 216 to be electrically connected to one another, and the conductivity enhancer 216A is in a region more susceptible to severer pressing and higher stress so as to provide pressure protection, further effectively preventing the electrode 218 from disconnection caused by pressing and stress, and improving reliability and luminescence performance of the organic light emitting element 10.

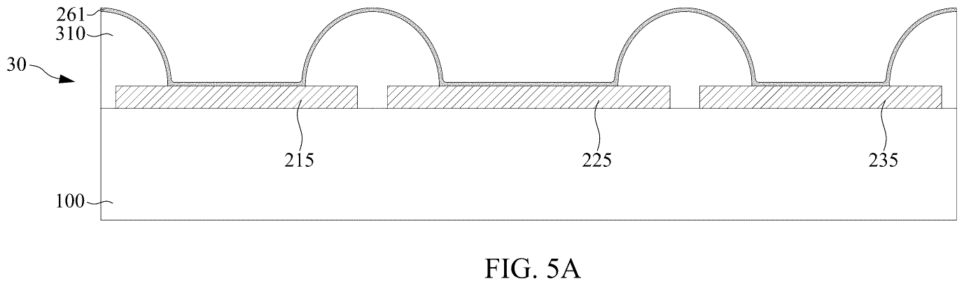

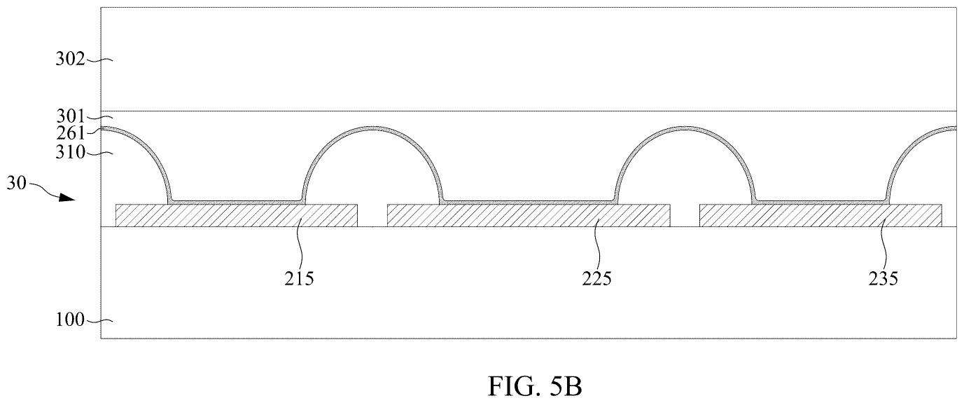

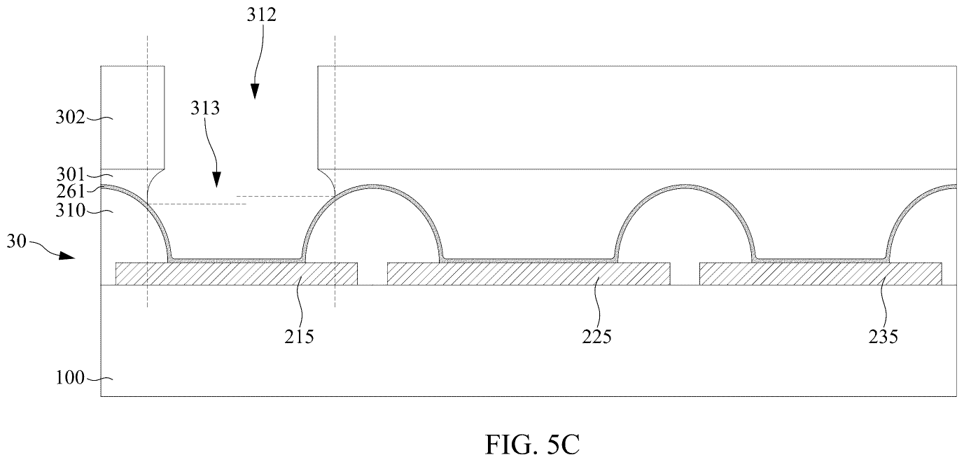

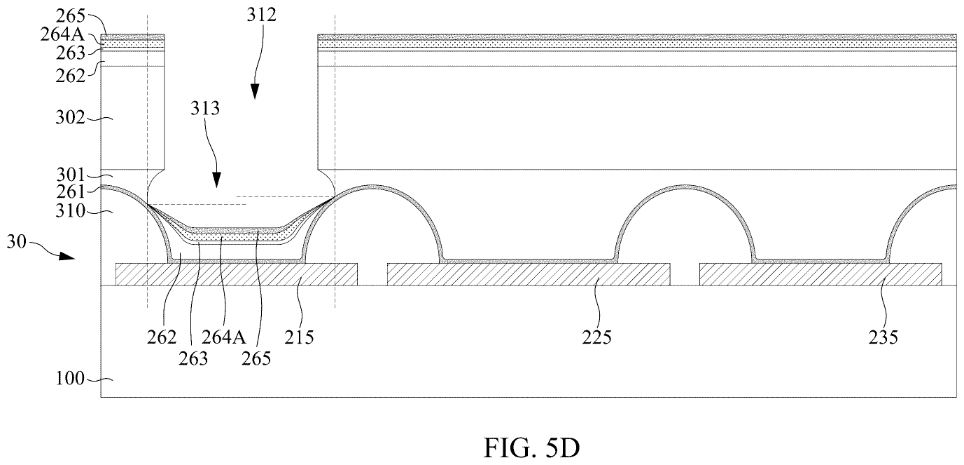

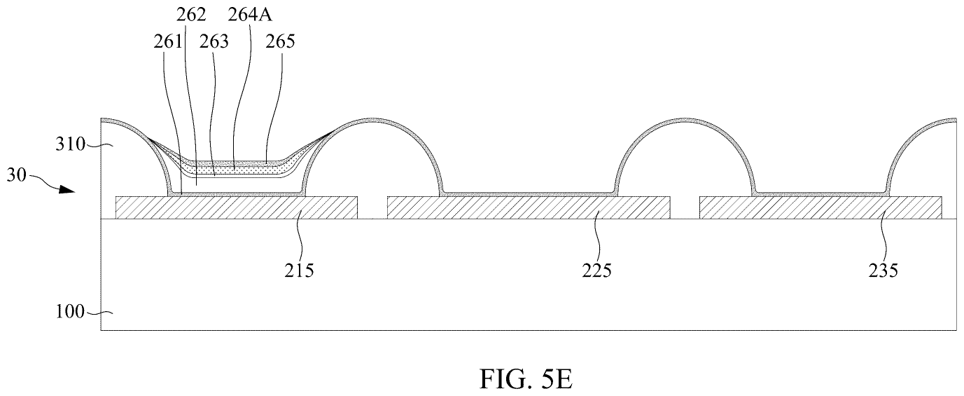

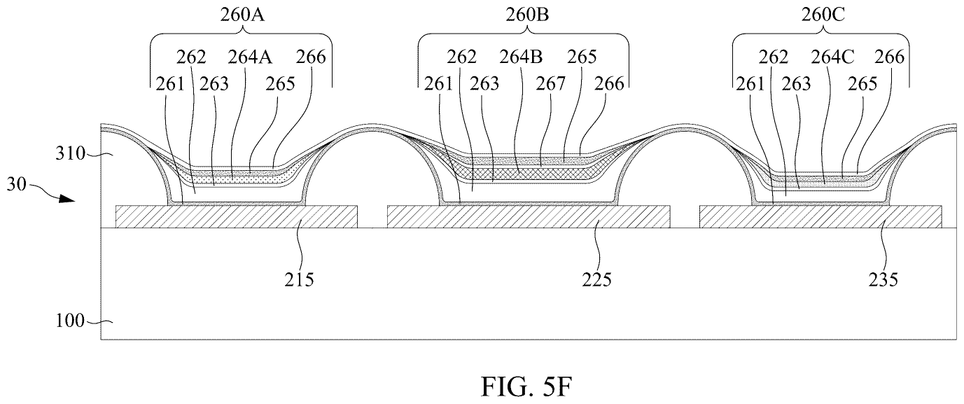

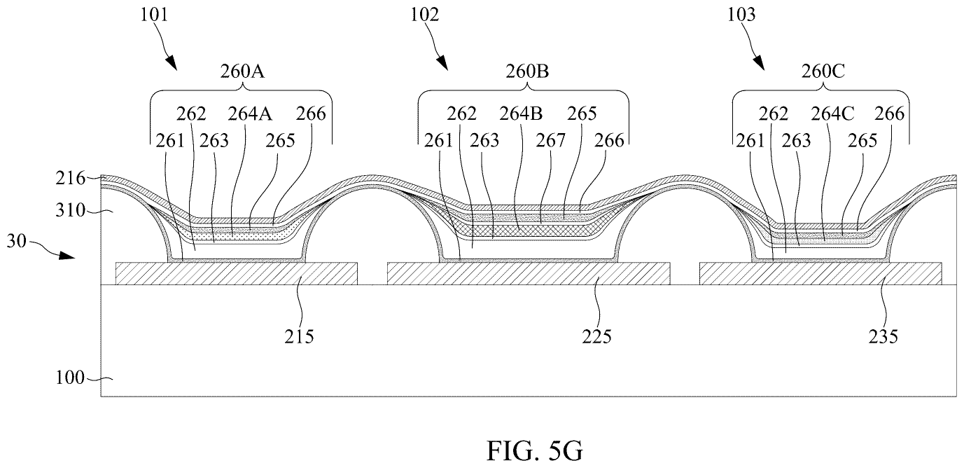

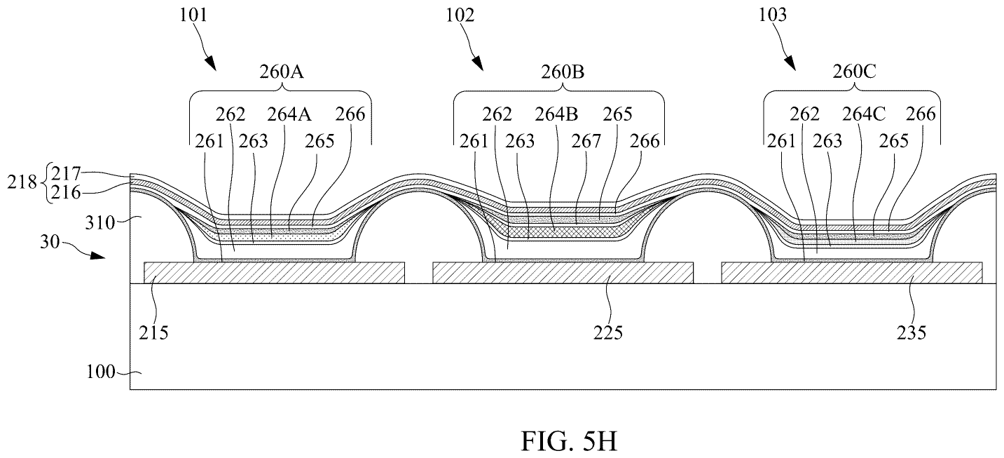

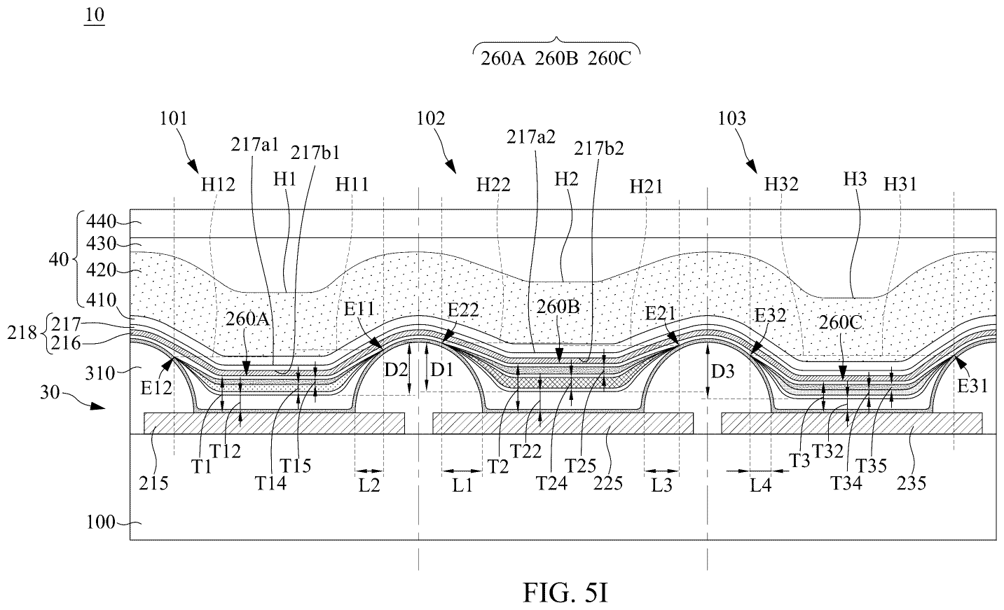

FIG. 5A to FIG. 5I depict a manufacturing method of an organic light emitting element 10 according to some embodiments.

As shown in FIG. 5A, in some embodiments, a substrate 100 is provided, a plurality of electrodes 215, 225 and 235 are disposed over the substrate 100, and a plurality of protrusions 310 (or a spacer structure 30) are formed, wherein each of the protrusions 310 fills a gap between the adjacent electrodes 215, 225 and 235. Next, in some embodiments, a hole injection layer (HIL) 261 is disposed on surfaces of the protrusions 310 and the electrodes 215, 225 and 235. In some embodiments, the hole injection layer (HIL) 261 is formed by means of evaporation.

As shown in FIG. 5B, in some embodiments, a buffer layer 301 is disposed over the protrusions 310, and the buffer layer 301 also covers the hole injection layer (HIL) 261 and the electrodes 215, 225 and 235. The buffer layer 301 is used to block moisture from passing through or entering the protrusions 310 and the hole injection layer (HIL) 261. Next, in some embodiments, a photosensitive layer 302 is disposed over the buffer layer 301. In some embodiments, the buffer layer 301 and the photosensitive layer 302 are formed by means of coating.

As shown in FIG. 5C, in some embodiments, the photosensitive layer 302 is patterned by a lithography process, such that a portion of the buffer layer 301 is exposed through a groove 312. Next, in some embodiments, a portion of the buffer layer 301 is removed to form a groove 313, so as to expose the hole injection layer (HIL) 261. In some embodiments, the buffer layer 301 is removed by means of a wet etching process.

As shown in FIG. 5D, in some embodiments, a hole transport layer (HTL) 262 is disposed over the hole injection layer (HIL) 261, an electron barrier layer (EBL) 263 is disposed over the hole transport layer (HTL) 262, an organic emission layer (EML) 264A is disposed over the electron barrier layer (EBL) 263, and an electron transport layer (ETL) 265 is disposed over the organic emission layer (EML) 264A. In some embodiments, the hole transport layer (HTL) 262, the electron barrier layer (EBL) 263, the organic emission layer (EML) 264A and the electron transport layer (ETL) 265 are formed by means of evaporation.

As shown in FIG. 5E, in some embodiments, the buffer layer 301, the photosensitive layer 302, and portions of the hole transport layer (HTL) 262, the electron barrier layer (EBL) 263, the organic emission layer (EML) 264A and the electron transport layer (ETL) 265 above the photosensitive layer 302 are removed. In some embodiments, the buffer layer 301, the photosensitive layer 302, a portion of the hole transport layer (HTL) 262, a portion of the electron barrier layer (EBL) 263, a portion of the organic emission layer (EML) 264A and a portion of the electron transport layer (ETL) 265 are removed by means of a wet etching process.

As shown in FIG. 5F, in some embodiments, the steps in FIG. 5B to FIG. 5E are repeated to form the hole transport layer 262, the electron barrier layer 263, the organic emission layer 264B and the electron transport layer 265 over the electrode 225, and form the hole transport layer 262, the electron barrier layer 263, the organic emission layer 264C and the electron transport layer 265 over the electrode 235. Next, in some embodiments, an electron injection layer (EIL) 266 is disposed over the protrusions 310 and the electron transport layer (ETL) 265. Up to this point, the organic light emitting layers 260A, 260B and 260C (or a light emitting layer 20) are formed.

As shown in FIG. 5G, in some embodiments, an electrode layer 216 is disposed over the organic light emitting layers 260A, 260B and 260C and the spacer structure 30.

As shown in FIG. 5H, in some embodiments, a conductivity enhancer 217 is disposed over the electrode layer 216. The electrode layer 216 and the conductivity enhancer 217 may form the electrode 218 (or referred to as a top electrode or a common electrode). In some embodiments, the conductivity enhancer 217 is formed over the electrode layer 216 and at least partially covers the electrode layer 216. In some embodiments, the conductivity enhancer 217 is partially above the organic light emitting layer 260B. In some embodiments, the conductivity enhancer 217 is partially above the protrusion 310. In some embodiments, the organic light emitting layers 260A, 260B and 260C (or the light emitting layer 20) are formed at a first process temperature, the conductivity enhancer 217 is formed at a second process temperature, and the second process temperature is less than the first process temperature. In some embodiments, the second process temperature at which the conductivity enhancer 217 is formed is less than 100° C. In some embodiments, the conductivity enhancer 217 includes indium zinc oxide (IZO) or an IZO layer. In some embodiments, a process temperature at which the IZO layer is formed is less than 100° C. In some embodiments, the conductivity enhancer 217 does not include ITO. Up to this point, the organic light emitting units 101, 102 and 103 are formed.

According to some embodiments of the present disclosure, by manufacturing or forming the conductivity enhancer 217 using IZO, not only the organic material of the organic light emitting layer is not damaged by the manufacturing process of the conductivity enhancer 217 because the process temperature of IZO is lower than the process temperature of the organic light emitting layer, but also IZO has high transparency such that the luminescence intensity remains substantially unaffected while a compressive strength is provided.

As shown in FIG. 5I, in some embodiments, a capping layer 410 is disposed over the conductivity enhancer 217, an encapsulation layer 420 is disposed over the capping layer 410, a filler layer 430 is disposed over the encapsulation layer 420, and a cover plate 440 is disposed over the filler layer 430. In some embodiments, the capping layer 410 is formed by means of evaporation. In some embodiments, the encapsulation layer 420 is formed by means of plasma enhanced chemical vapor deposition (PECVD). Up to this point, a cover layer 40 including the capping layer 410, the encapsulation layer 420, the filler layer 430 and the cover plate 440 is formed. As shown in FIG. 5I, up to this point, the organic light emitting element 10 shown in FIG. 2 is formed.

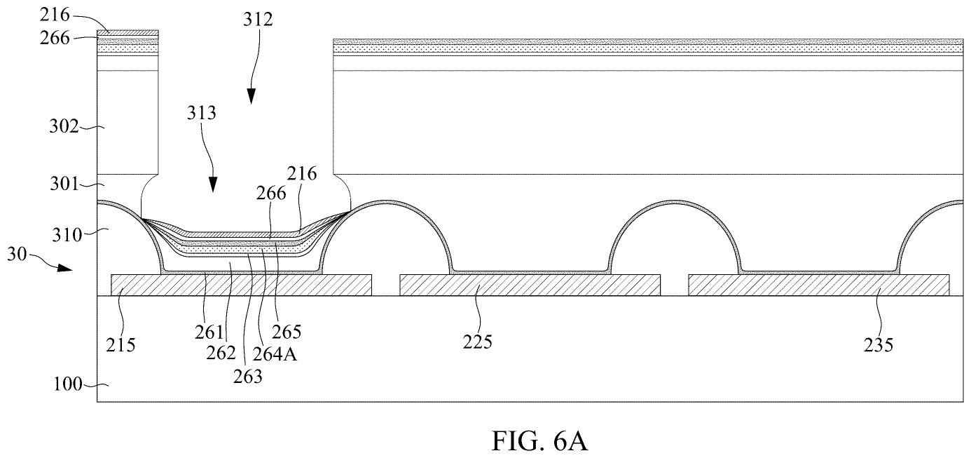

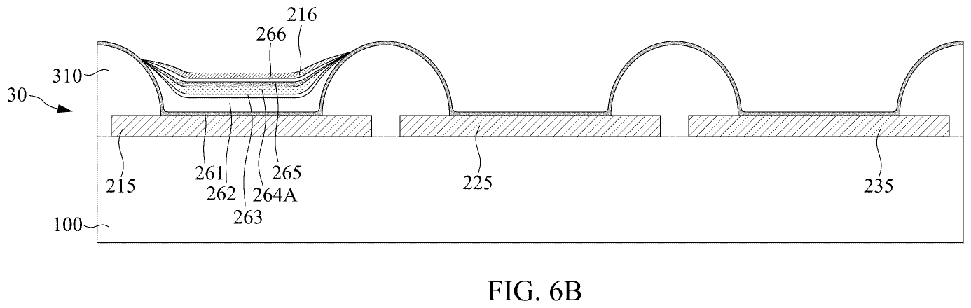

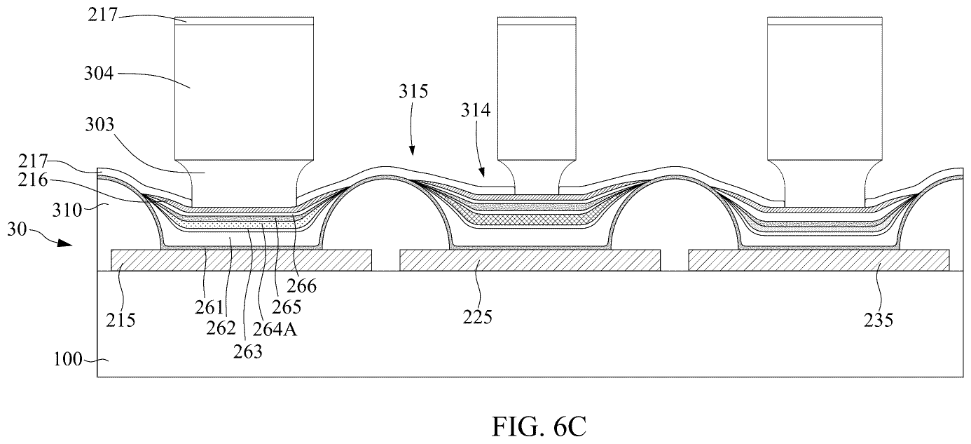

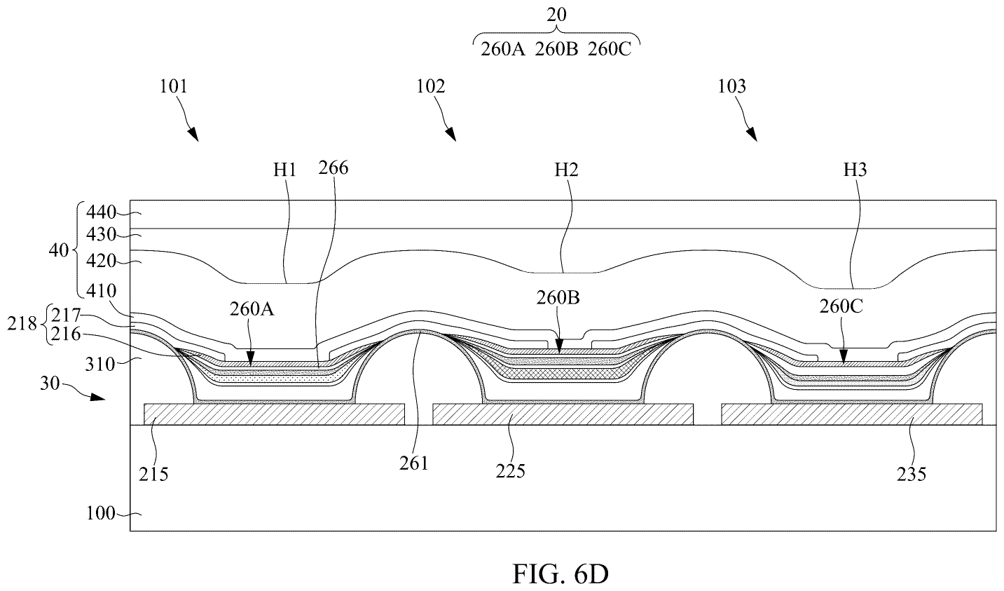

FIG. 6A to FIG. 6D depict a manufacturing method of an organic light emitting element 10 according to some embodiments.

As shown in FIG. 6A, in some embodiments, the steps in FIG. 5A to FIG. 5C are repeated to manufacture the structure shown in FIG. 5C. Next, in some embodiments, a hole transport layer (HTL) 262 is disposed over a hole injection layer (HIL) 261, an electron barrier layer (EBL) 263 is disposed over the hole transport layer (HTL) 262, an organic emission layer (EML) 264A is disposed over the electron barrier layer (EBL) 263, an electron transport layer (ETL) 265 is disposed over the organic emission layer (EML) 264A, an electron injection layer (EIL) 266 is disposed over the electron transport layer (ETL) 265, and an electrode layer 216 is disposed over the electron injection layer (EIL) 266. In some embodiments, the hole transport layer (HTL) 262, the electron barrier layer (EBL) 263, the organic emission layer (EML) 264A, the electron transport layer (ETL) 265, the electron injection layer (EIL) 266 and the electrode layer 216 are formed by means of evaporation.

As shown in FIG. 6B, in some embodiments, the buffer layer 301, the photosensitive layer 302, and portions of the hole transport layer (HTL) 262, the electron barrier layer (EBL) 263, the organic emission layer (EML) 264A, the electron transport layer (ETL) 265, the electron injection layer (EIL) 266 and the electrode layer 216 above the photosensitive layer 302 are removed. In some embodiments, the buffer layer 301, the photosensitive layer 302, a portion of the hole transport layer (HTL) 262, a portion of the electron barrier layer (EBL) 263, a portion of the organic emission layer (EML) 264A, a portion of the electron transport layer (ETL) 265, a portion of the electron injection layer (EIL) 266, and a portion of the electrode layer 216 are removed by means of a wet etching process.

As shown in FIG. 6B, in some embodiments, in some embodiments, a hole transport layer (HTL) 262 is disposed over a hole injection layer (HIL) 261, an electron barrier layer (EBL) 263 is disposed over the hole transport layer (HTL) 262, an organic emission layer (EML) 264A is disposed over the electron barrier layer (EBL) 263, and an electron transport layer (ETL) 265 is disposed over the organic emission layer (EML) 264A. In some embodiments, the hole transport layer (HTL) 262, the electron barrier layer (EBL) 263, the organic emission layer (EML) 264A and the electron transport layer (ETL) 265 are formed by means of evaporation.

As shown in FIG. 6C, in some embodiments, a buffer layer 303 is disposed over the organic light emitting layers 260A, 260B and 260C, and the buffer layer 303 also covers the electrode layer 216. Next, in some embodiments, a photosensitive layer 304 is disposed over the buffer layer 303. In some embodiments, the buffer layer 303 and the photosensitive layer 304 are formed by means of coating.

As shown in FIG. 6C, in some embodiments, the photosensitive layer 304 is patterned by a lithography process, such that a portion of the buffer layer 303 is exposed through a groove 316. Next, in some embodiments, a portion of the buffer layer 303 is removed to form a groove 314, so as to expose the electrode layer 216 and top portions of the protrusions 310. In some embodiments, the buffer layer 303 is removed by means of a wet etching process. Next, in some embodiments, a conductivity enhancer 217 is disposed over the electrode layer 216 and the protrusions 310. The electrode layer 216 and the conductivity enhancer 217 may form the electrode 218 (or referred to as a top electrode or a common electrode). In some embodiments, the conductivity enhancer 217 is formed by means of evaporation. In some embodiments, the organic light emitting layers 260A, 260B and 260C (or the light emitting layer 20) are formed at a first process temperature, the conductivity enhancer 217 is formed at a second process temperature, and the second process temperature is less than the first process temperature. In some embodiments, the second process temperature at which the conductivity enhancer 217 is formed is less than 100° C. In some embodiments, the conductivity enhancer 217 includes indium zinc oxide (IZO). In some embodiments, a process temperature at which the IZO layer is formed is less than 100° C. In some embodiments, the conductivity enhancer 217 does not include ITO. Up to this point, the organic light emitting units 101, 102 and 103 are formed.

As shown in FIG. 6D, in some embodiments, the buffer layer 303, the photosensitive layer 304, and a portion of the conductivity enhancer 217 above the photosensitive layer 304 are removed. In some embodiments, the buffer layer 303, the photosensitive layer 304, and a portion of the conductivity enhancer 217 are removed by means of a wet etching process.

As shown in FIG. 6D, in some embodiments, a capping layer 410 is disposed over the conductivity enhancer 217, an encapsulation layer 420 is disposed over the capping layer 410, a filler layer 430 is disposed over the encapsulation layer 420, and a cover plate 440 is disposed over the filler layer 430. In some embodiments, the capping layer 410 is formed by means of evaporation. In some embodiments, the encapsulation layer 420 is formed by means of plasma enhanced chemical vapor deposition (PECVD). Up to this point, a cover layer 40 including the capping layer 410, the encapsulation layer 420, the filler layer 430 and the cover plate 440 is formed. As shown in FIG. 6D, up to this point, the organic light emitting element shown in FIG. 3F is formed.

According to some embodiments of the present disclosure, the conductivity enhancer 217 and the patterned organic light emitting layers 260A, 260B and 260C are completed in the same step, and have substantially the same pattern. Thus, manufacturing processes can be simplified, and time and costs needed for multiple rounds of patterning can be reduced.

The features of some embodiments are described in brief above for a person skilled in the art to better understand various aspects of the present disclosure. A person skilled in the art would be able to understand that the present disclosure can be used as the basis for designing or modifying other manufacturing processes and structures so as to achieve the same objects and/or the same advantages of the embodiments described in the present application. A person skilled in the art would also be able to understand that such structures do not depart from the spirit and scope of the present disclosure, and various changes, substitutions and replacements may be made to the embodiments by a person skilled in the art without departing from the spirit and scope of the present disclosure.

What is claimed is:

1. An organic light emitting element, comprising:
a substrate;
a first electrode over the substrate;
a first organic light emitting layer over the first electrode; and
a top electrode, comprising:
an electrode layer over the first organic light emitting layer; and
a conductivity enhancer at least partially covering the electrode layer.

2. The organic light emitting element according to claim 1, wherein the conductivity enhancer substantially completely covers the electrode layer.

3. The organic light emitting element according to claim 2, further comprising:
a second electrode over the substrate; and
a second organic light emitting layer over the second electrode, wherein a thickness of the second organic light emitting layer is greater than a thickness of the first organic light emitting layer, and the conductivity enhancer contacts and covers the electrode layer above the second organic light emitting layer.

4. The organic light emitting element according to claim 1, wherein the electrode layer comprises a first metal material, the conductivity enhancer comprises a second metal material different from the first metal material, and a compressive strength of the second metal material is greater than a compressive strength of the first metal material.

5. The organic light emitting element according to claim 1, wherein the electrode layer comprises a silver layer, and the conductivity enhancer comprises a transparent conductive material.

6. The organic light emitting element according to claim 5, wherein the transparent conductive material comprises a conductive metal oxide.

7. The organic light emitting element according to claim 1, further comprising:
a first insulating protrusion and a second insulating protrusion on the substrate, wherein the first organic light emitting layer is in a recess between the first insulating protrusion and the second insulating protrusion, and the conductivity enhancer is at least partially above the first insulating protrusion and the second insulating protrusion.

8. The organic light emitting element according to claim 7, wherein the conductivity enhancer is at least partially not located above the first organic light emitting layer.

9. The organic light emitting element according to claim 7, wherein from a cross-sectional view perspective, the conductivity enhancer comprises a first portion covering the first insulating protrusion and a second portion covering the second insulating protrusion, and the first portion and the second portion have different thicknesses.

10. The organic light emitting element according to claim 7, wherein the electrode layer is at least partially not located at a top portion of the first insulating protrusion and a top portion of the second insulating portion.

11. The organic light emitting element according to claim 1, wherein the electrode layer and the conductivity enhancer comprise a same metal material.

12. The organic light emitting element according to claim 1, further comprising:
a second electrode over the substrate; and
a second organic light emitting layer over the second electrode, wherein a thickness of the second organic light emitting layer is greater than a thickness of the first organic light emitting layer, and the conductivity enhancer is at least partially above the second organic light emitting layer.

13. The organic light emitting element according to claim 12, wherein the conductivity enhancer is at least partially not located above the first organic light emitting layer.

14. The organic light emitting element according to claim 12, wherein a luminescence wavelength of the second organic light emitting layer is greater than a luminescence wavelength of the first organic light emitting layer.

15. A manufacturing method of an organic light emitting element, comprising:
providing a substrate;
disposing a first electrode over the substrate;
forming a first organic light emitting layer over the first electrode;
forming an electrode layer over the first organic light emitting layer; and
forming a conductivity enhancer over the electrode layer to at least partially cover the electrode layer.

16. The manufacturing method according to claim 15, wherein the first organic light emitting layer is formed at a first process temperature, the conductivity enhancer is formed at a second process temperature, and the second process temperature is less than the first process temperature.

17. The manufacturing method according to claim 15, wherein the electrode layer comprises silver, and the conductivity enhancer comprises indium zinc oxide (IZO).

18. The manufacturing method according to claim 15, further comprising:
disposing a second electrode over the substrate; and
forming a second organic light emitting layer over the second electrode, wherein a thickness of the second organic light emitting layer is greater than a thickness of the first organic light emitting layer, and the conductivity enhancer is at least partially above the second organic light emitting layer.

19. The manufacturing method according to claim 15, further comprising:
forming a first insulating protrusion and a second insulating protrusion on the substrate, wherein the first organic light emitting layer is formed in a recess between the first insulating protrusion and the second insulating protrusion, and the conductivity enhancer is at least partially formed above the first insulating protrusion and the second insulating protrusion.

20. The manufacturing method according to claim 19, wherein the electrode layer is at least partially not formed at a top portion of the first insulating protrusion and a top portion of the second insulating portion.

21. The manufacturing method according to claim 19, wherein the conductivity enhancer is at least partially not formed above the first organic light emitting layer.
